(19) United States
(12) Patent Application Publication
(10) Pub. No.: US 2018/0066002 A1
(43) Pub. Date: Mar. 8, 2018

(54) ORGANOMETALLIC COMPOUND AND ORGANIC LIGHT-EMITTING DEVICE EMPLOYING THE SAME

(71) Applicant: INDUSTRIAL TECHNOLOGY RESEARCH INSTITUTE, Hsinchu (TW)

(72) Inventors: Jin-Sheng LIN, Taipei City (TW); Jia-Lun LIOU, Hengshan Township (TW); Meng-Hao CHANG, New Taipei City (TW); Han-Cheng YEH, Taipei City (TW)

(73) Assignee: INDUSTRIAL TECHNOLOGY RESEARCH INSTITUTE, Hsinchu (TW)

(21) Appl. No.: 15/806,589

(22) Filed: Nov. 8, 2017

Related U.S. Application Data
(63) Continuation-in-part of application No. 15/178,761, filed on Jun. 10, 2016.

(30) Foreign Application Priority Data
Dec. 4, 2015 (TW) 104140698
Nov. 11, 2016 (TW) 105137156

(51) Int. Cl. C07F 15/00; C09K 11/06; H01L 51/00

(52) U.S. Cl. CPC C07F 15/0033; H01L 51/5016; H01L 51/0094; C09K 11/06

(57) ABSTRACT

Organometallic compounds and organic electroluminescence devices employing the same are provided. The organometallic compound has a chemical structure represented below:

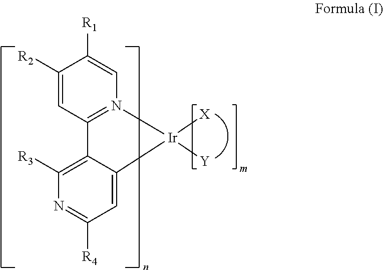

In Formula (I), one of R1 and R2 is trimethylsilyl (TMS) and the other is hydrogen, at least one of R3 and R4 is fluorine or C1-6 alkyl, or one of R3 and R4 is fluorine and the other is C1-6 alkyl,

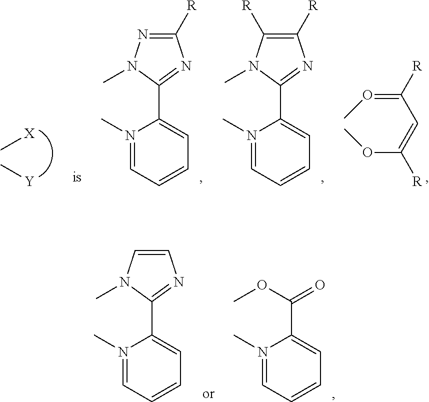

n is 2 or 3, and m is 0 or 1, wherein n+m=3.

### CROSS REFERENCE TO RELATED APPLICATIONS

This application claims priority of Taiwan Patent Application No. 105137156, filed on Nov. 11, 2016, and this application is a Continuation-In-Part of application Ser. No. 15/178,761, filed on Jun. 10, 2016, which claims priority of Taiwan Patent Application No. 104140698, filed on Dec. 4, 2015, the entireties of which are incorporated by reference herein.

### TECHNICAL FIELD

The disclosure relates to an organometallic compound and an organic light-emitting device employing the same.

### BACKGROUND

Organic light-emitting devices are popular in flat panel display due to their high illumination, light weight, self-illumination, low power consumption, simple fabrication, rapid response time, wide viewing angle, and no backlight requirement.

Generally, an organic electroluminescent device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence.

Considering the luminescence mechanism of phosphorescent materials in OLED devices, in order to achieve the best luminescence efficiency and quantum efficiency, the host materials with proper energy levels are required. Among them, blue phosphorescent host materials need a larger energy level gap and thermal stability. Therefore, the structural design for such host materials will be of corresponding difficulty.

Therefore, there is a need for a novel phosphorescent material to increase the emissive efficiency of an OLED.

### SUMMARY

According to an embodiment of the disclosure, the disclosure provides an organometallic compound having a structure represented by the following Formula (I):

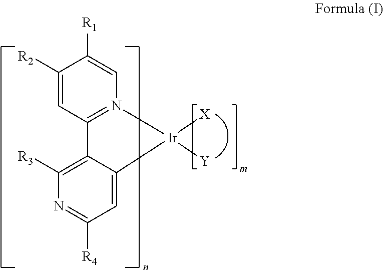

In Formula (I), one of R₁ and R₂ is trimethylsilyl (TMS) and the other is hydrogen, at least one of R₃ and R₄ is fluorine or C₁₋₆ alkyl, or one of R₃ and R₄ is fluorine and the other is C₁₋₆ alkyl,

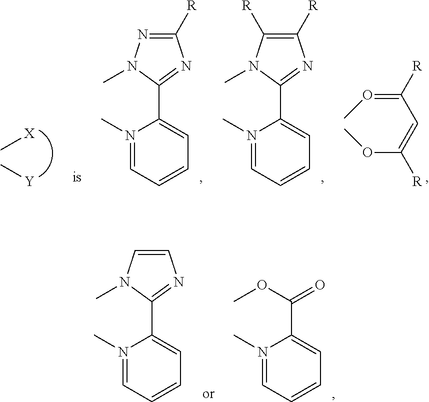

R is CH₃ [symbol] CH₂CH₃ [symbol] CH(CH₃)₂ [symbol] C(CH₃)₃ [symbol] CF₃ [symbol] CHF₂ [symbol] C₃F₈ or phenyl, n is 2 or 3, and m is 0 or 1, wherein n+m=3.

According to another embodiment of the disclosure, the disclosure provides an organic light-emitting device. The device includes an anode, a cathode and an organic light-emitting element disposed between the anode and the cathode. The organic light-emitting element includes the aforementioned organometallic compound.

According to another embodiment of the disclosure, the disclosure provides an organic light-emitting device. The device includes an anode, a cathode and an organic light-emitting element disposed between the anode and the cathode. The organic light-emitting element includes a first light-emitting layer. The first light-emitting layer includes the aforementioned organometallic compound.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross section of an organic light-emitting device disclosed by an embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

According to an embodiment of the disclosure, the disclosure provides an organometallic compound having a structure represented by the following Formula (I):

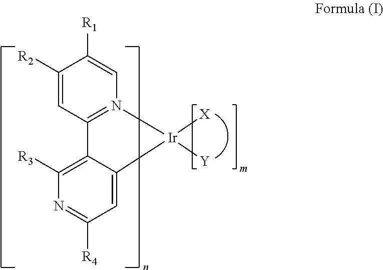

In Formula (I), one of R₁ and R₂ may be trimethylsilyl (TMS) and the other is hydrogen, at least one of R₃ and R₄ is fluorine or C₁₋₆ alkyl, or one of R₃ and R₄ may be fluorine and the other may be C₁₋₆ alkyl,

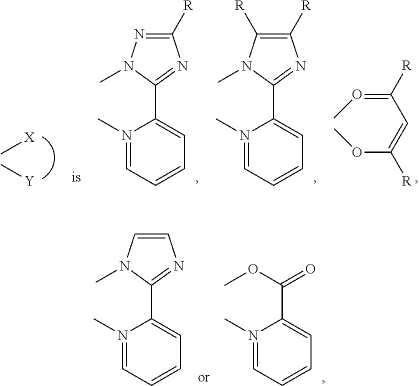

R may be CH₃ [symbol] CH₂CH₃ [symbol] CH(CH₃)₂ [symbol] C(CH₃)₃ [symbol] CF₃ [symbol] CHF₂ [symbol] C₃F₈ or phenyl, n may be 2 or 3, and m may be 0 or 1, wherein n+m=3.

According to an embodiment of the disclosure, the organometallic compound may have a structure represented by Formula (II):

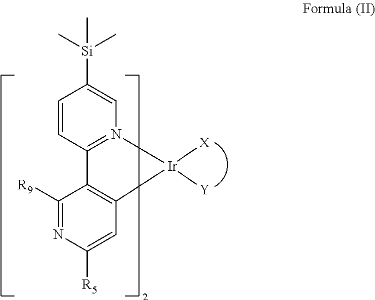

In Formula (II), R₅ may be fluorine or C₁₋₆ alkyl,

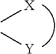

may be

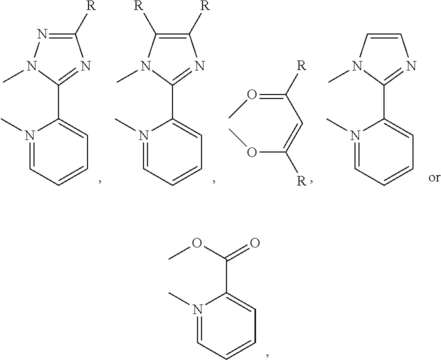

R may be CH₃, CH₂CH₃, CH(CH₃)₂, C(CH₃)₃, CF₃, CHF₂, C₃F₈ or phenyl.

According to an embodiment of the disclosure, the organometallic compound may have a structure represented by Formula (III) or Formula (IV):

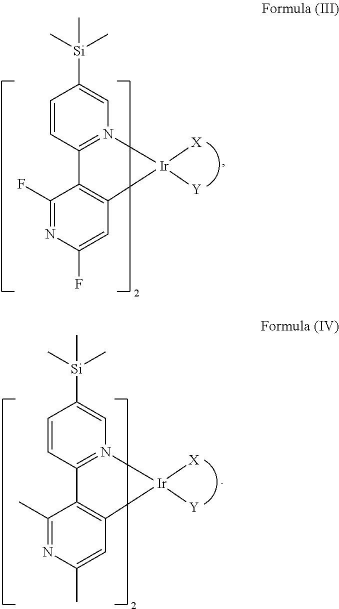

In Formula (III) or Formula (IV)

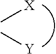

may be

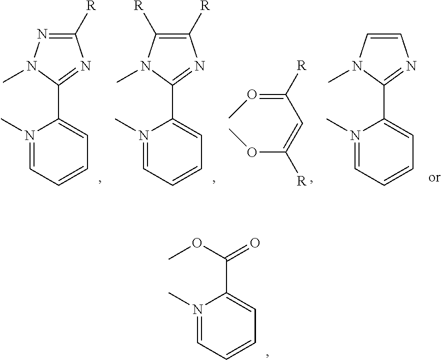

R may be CH₃, CH₂CH₃, CH(CH₃)₂, C(CH₃)₃, CF₃, CHF₂, C₃F₈ or phenyl.

According to an embodiment of the disclosure, the organometallic compound may be

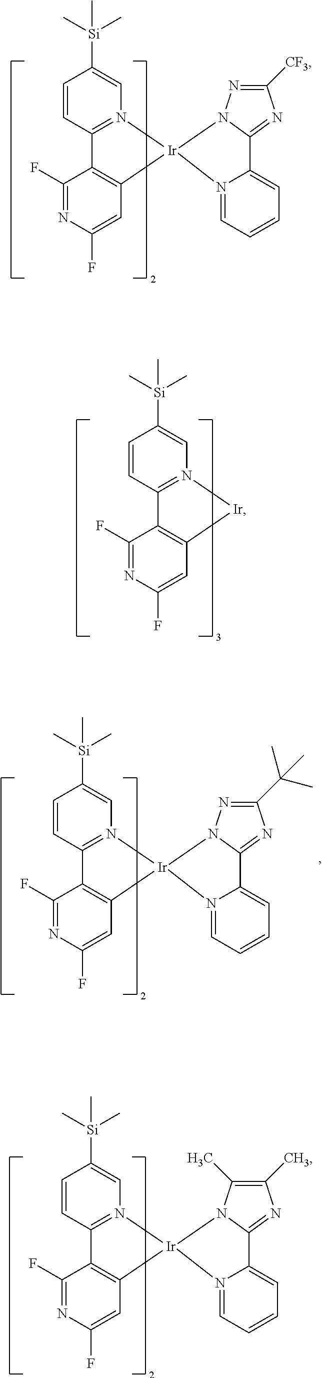

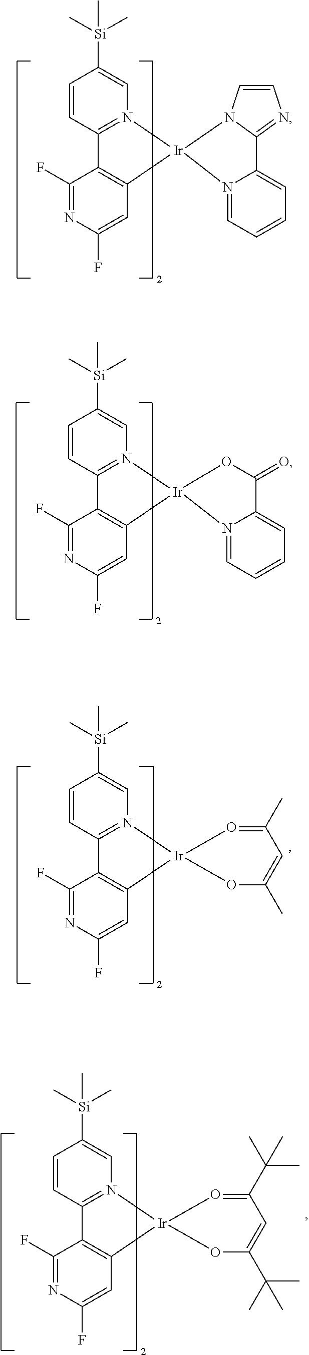

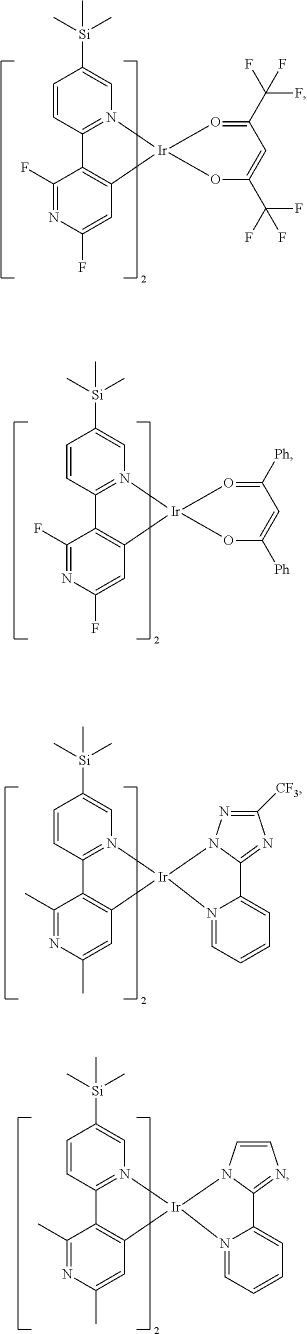

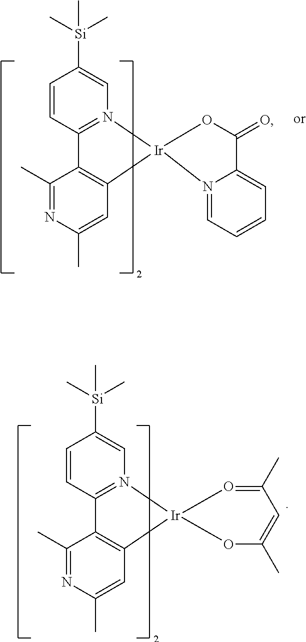

According to another embodiment of the disclosure, the disclosure provides an organic light-emitting device. The device includes an anode, a cathode and an organic light-emitting element disposed between the anode and the cathode. The organic light-emitting element includes the aforementioned organometallic compound.

According to another embodiment of the disclosure, the disclosure provides an organic light-emitting device. The device includes an anode, a cathode and an organic light-emitting element disposed between the anode and the cathode. The organic light-emitting element includes a first light-emitting layer. The first light-emitting layer includes the aforementioned organometallic compound.

According to another embodiment of the disclosure, the organic light-emitting element further includes a second light-emitting layer disposed between the anode and the first light-emitting layer or between the first light-emitting layer and the cathode. The second organic light-emitting layer includes the aforementioned organometallic compound.

According to another embodiment of the disclosure, The organic light-emitting device may emit blue light.

The organometallic compounds according to Formula (I)-(IV) of the disclosure include the compounds shown in Table 1.

TABLE 1

| Example | Structure | abbreviation |
|---|---|---|
| 1 | 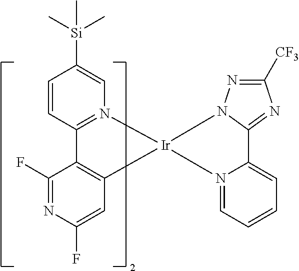 | DFTIr(taz) |
| 2 | 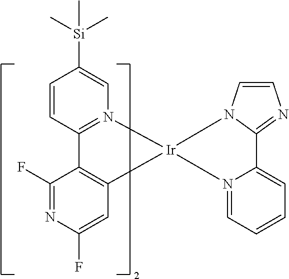 | DFTIr(iaz) |
| 3 | 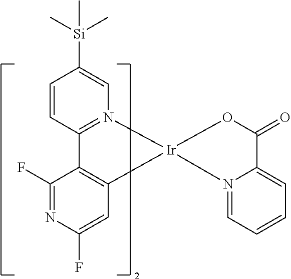 | DFTIr(pic) |
| 4 | 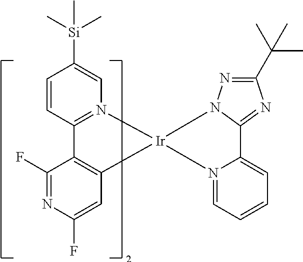 | DFTIr(taz2) |
| 5 | 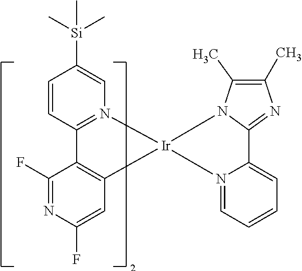 | DFTIr (Miaz) |
| 6 | 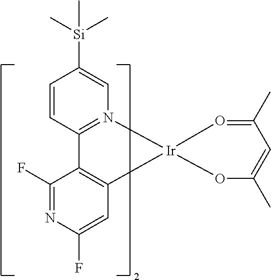 | DFTIr(acac) |
| 7 | 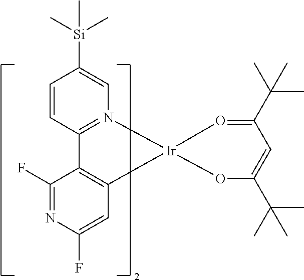 | DFTIr(tmd) |
| 8 | 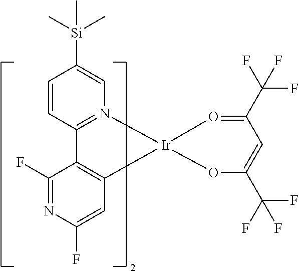 | DFTIr(hf) |
| 9 | 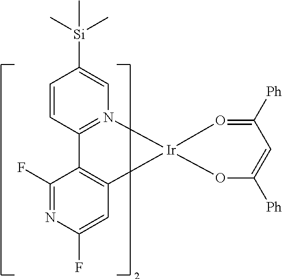 | DFTIr(dbm) |
| 10 | 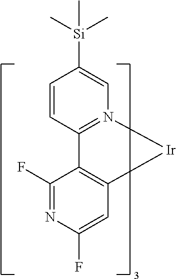 | DFTIr |
| 11 | 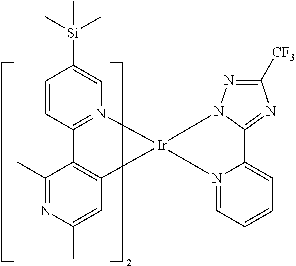 | DMTIr(taz) |
| 12 | 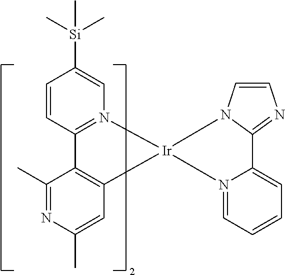 | DMTIr(iaz) |
| 13 | 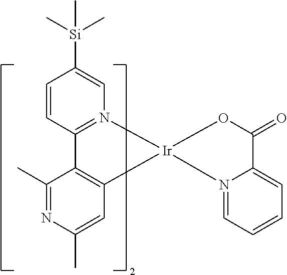 | DMTIr(pic) |
| 14 | 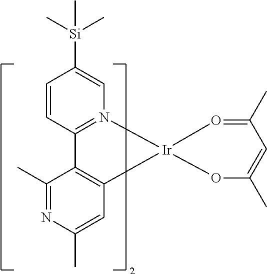 | DMTIr (acac) |

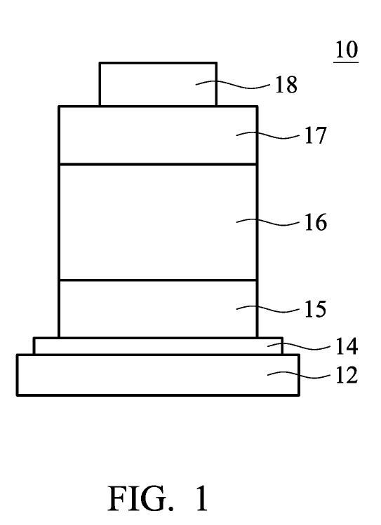

FIG. 1 shows an embodiment of an organic light-emitting device 10. The organic light-emitting device 10 includes a substrate 12, an anode 14, an organic light-emitting element 16, and a cathode 18, as shown in FIG. 1. The anode 14 is disposed on the substrate 12, the organic light-emitting element 16 is disposed on the anode 14, and the cathode 18 is disposed on the organic light-emitting element 16.

The organic light-emitting element 16 at least includes a first organic light-emitting layer, and can further include a hole injection layer, a hole transport layer, an electron transport layer, and an electron injection layer. In an embodiment of the disclosure, at least one layer of the organic light-emitting element 16 includes the aforementioned organometallic compounds.

The organic light-emitting device can be a top-emission, bottom-emission, or dual-emission device. The substrate 12 can be a glass, plastic, or semiconductor substrate. Suitable materials for the anode 14 can be indium tin oxide (ITO), indium zinc oxide (IZO), aluminum zinc oxide (AZO), or zinc oxide (ZnO). Suitable materials for the cathode 18 can be Ca, Ag, Mg, Al, Li, In, Au, Ni, W, Pt, or Cu. The organic light-emitting layer can be formed by sputtering, electron beam evaporation, thermal evaporation, or chemical vapor deposition. Furthermore, at least one of the anode 14 and cathode 18 is transparent.

According to embodiments of the disclosure, Suitable materials for the hole transport layer and the electron transport layer can be

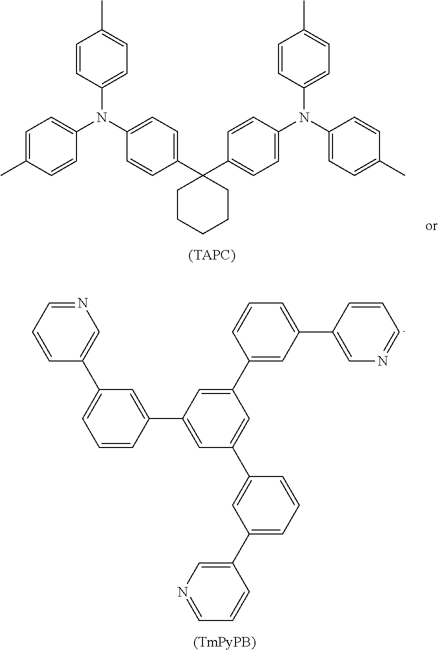

According to embodiments of the disclosure, the organic light-emitting element 16 can emit blue or green light under a bias voltage.

According to embodiments of the disclosure, the organic light-emitting element 16 can further include a second organic light-emitting layer disposed between the anode 14 and the first light-emitting layer or between the first light-emitting layer and the cathode 18. The second organic light-emitting layer includes the aforementioned organometallic compound.

According to embodiments of the disclosure, the first and second organic light-emitting layers at least include a host and a dopant.

According to embodiments of the disclosure, Suitable materials for the host can be

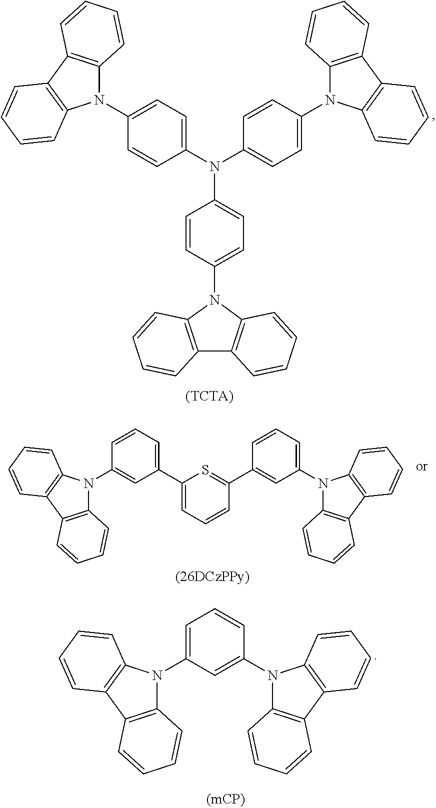

According to embodiments of the disclosure, Suitable materials for the dopant can include the aforementioned organometallic compounds.

The simple layered structure illustrated in FIG. 1 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting.

In order to clearly disclose the organic light-emitting devices of the disclosure, the following examples (employing the organometallic compounds of the disclosure) are intended to illustrate the disclosure more fully without limiting their scope, since numerous modifications and variations will be apparent to those skilled in this art. For example, when the organometallic compounds of the disclosure serves as a dopant material, the organometallic compounds of the disclosure can have a weight percentage from 0.1 wt % to 15 wt %, based on the weight of the host material.

### Example 1: Preparation of Organometallic Compound DFTIr(taz)

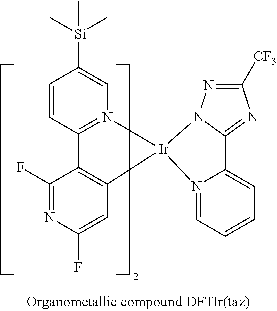

Firstly, after a 100 mL double-neck bottle was dried to remove the moisture and the air several times, 2,5-dibromopyridine (1 g, 4.22 mmol) and dehydrated ether (40 mL) were dropwise added into the bottle under nitrogen atmosphere. Next, after cooling to −78° C. and temperature equilibrating, n-BuLi (3 mL, 4.64 mmol) was dropwise added into the reaction bottle and subjected to reaction at −78° C. for 1 hours, and then TMSCl (0.65 mL, 5 mmol) was added thereto. The reaction was then warmed to room temperature and the reaction mixture was extracted three times using ethyl acetate (EA) and water as the extraction solvent. Next, an organic phase was separated and concentrated, and then purified by column chromatography (SiO₂, EA/Hexane=1/40), 2-bromo-5-trimethylsilylpyridine was obtained. The synthesis pathway of the above reaction was as follows:

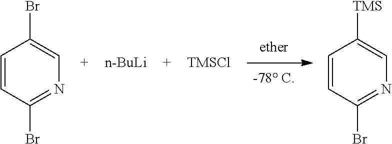 [SMILES: "TMSCl" ; "n-BuLi" ; Brc1ccc(Br)nc1 ; C[Si](C)(C)c1ccc(Br)nc1]

Next, 2-Bromo-5-trimethylsilylpyridine (0.7 g, 3 mmol), 2,6-difluoropyridine-3-bromic acid (0.52 g, 3.3 mmol), K₂CO₃ (0.4 g, 1 mmol), dimethoxyethane (20 mL), water (10 mL) and tetrakis(triphenylphosphine)palladium Pd(PPh₃)₄ (0.17 g, 0.15 mmol) were added into a 100 mL double-neck bottle. After the reaction bottle was dried to remove the moisture and the air therein, the reaction bottle was heated to reflux under nitrogen atmosphere and keep refluxing overnight. After cooling to room temperature, the reaction mixture was neutralized to weak alkalinity (pH 8 to 10) with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/40), a compound (A) was obtained. The synthesis pathway of the above reaction was as follows:

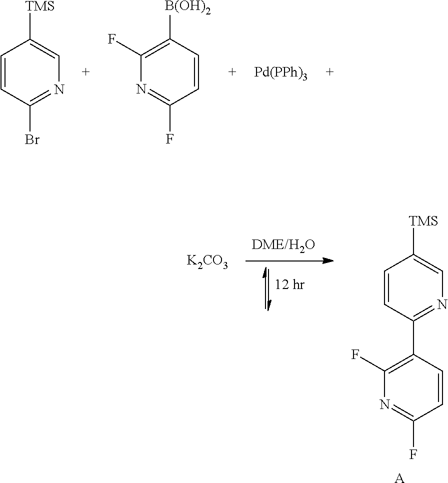

The compound A (1.7 g, 6.6 mmol), IrCl₃ (0.89 g, 3 mmol), 2-methoxyethanol (24 mL) and water (8 mL) were added into a 100 mL flask. After removing the moisture and the air therein, the reaction bottle was heated to 120° C. under nitrogen atmosphere and keep reacting overnight. After cooling to room temperature, water was added into the reaction mixture to produce precipitate. Then, the precipitate purified and dried under vacuum, and, obtaining a dimer A. The synthesis pathway of the above reaction was as follows:

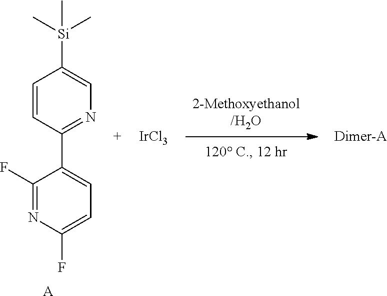

The dimer A (0.5 g, 0.33 mmol), ligand

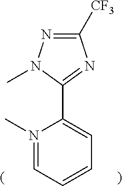

(285 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to produce precipitate. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(taz) was obtained. The synthesis pathway of the above reaction was as follows:

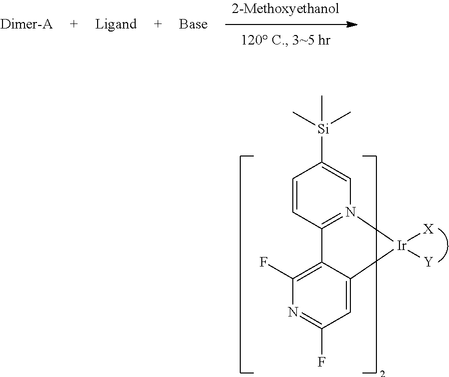

The physical measurement of the compound DFTIr(taz) is listed below: 1H NMR (200 MHz, CDCl3, 294 K): δ 8.37 (d, 1H), 8.25 (d, 1H), 8.21 (d, 1H), 8.02 (t, 1H), 7.90 (d, 2H), 7.83 (d, 1H), 7.58 (s, 1H), 7.38˜7.32 (m, 2H), 5.74 (t, 1H), 5.64 (t, 1H), 0.15 (s, 9H), 0.06 (s, 9H).

### Example 2: Preparation of Organometallic Compound DFTIr(iaz)

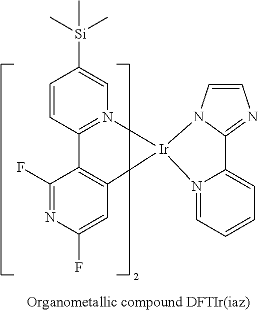

The dimer A (0.5 g, 0.33 mmol), ligand

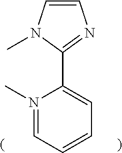

(193 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(iaz was obtained). The synthesis pathway of the above reaction was as follows:

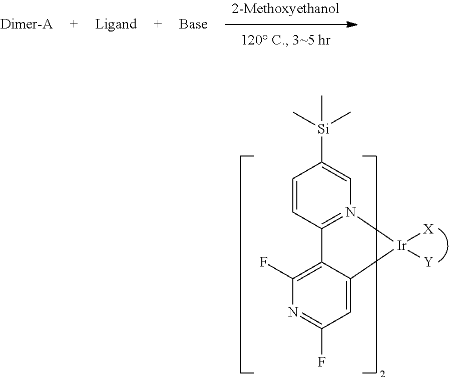

The physical measurement of the compound DFTIr(iaz) is listed below: 1H NMR (200 MHz, CDCl3, 294 K): δ 8.29˜8.17 (m, 3H), 7.88˜7.77 (m, 3H), 7.67 (d, 1H), 7.62 (s, 1H), 7.52 (s, 1H), 7.32 (s, 1H), 7.06 (t, 1H), 6.61 (s, 1H), 5.80 (t, 1H), 5.68 (t, 1H), 0.13 (s, 9H), 0.09 (s, 9H).

### Example 3: Preparation of Organometallic Compound DFTIr(pic)

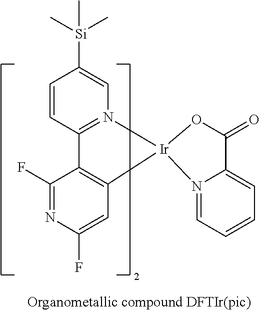

The dimer A (0.5 g, 0.33 mmol), ligand

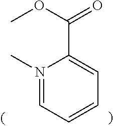

(193 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(pic) was obtained. The synthesis pathway of the above reaction was as follows:

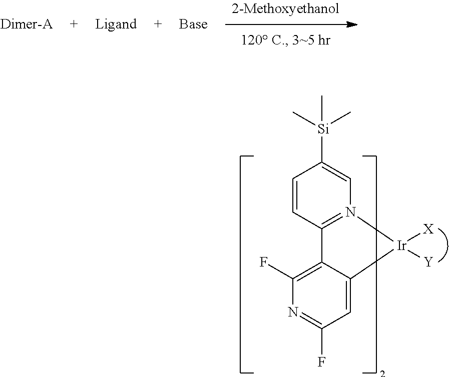

The physical measurement of the compound DFTIr(pic) is listed below: 1H NMR (200 MHz, CDCl3, 294 K): δ 8.78 (s, 1H), 8.38 (d, 1H), 8.27˜8.20 (m, 2H), 8.05 (dt, 1H), 7.80˜7.91 (m, 2H), 7.83 (d, 1H), 7.53 (t, 1H), 7.31 (s, 1H), 5.80 (s, 1H), 5.57 (s, 1H), 0.31 (s, 9H), 0.08 (s, 9H).

### Example 4: Preparation of Organometallic Compound DFTIr(taz2)

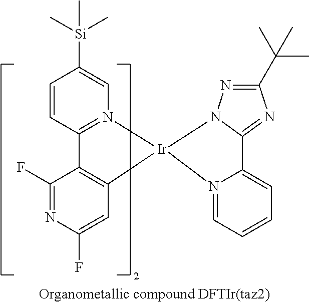

The dimer A (0.5 g, 0.33 mmol), ligand

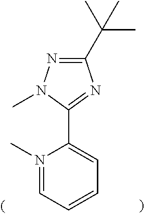

(269 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(taz2) was obtained. The synthesis pathway of the above reaction was as follows:

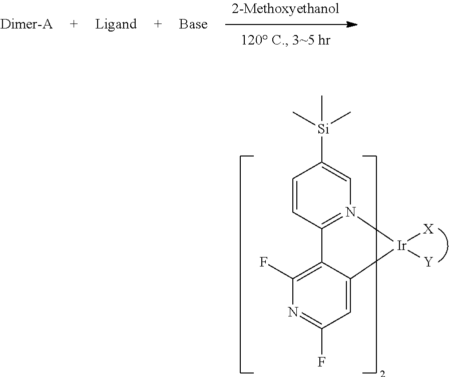

The physical measurement of the compound DFTIr(taz2) is listed below: 1H NMR (200 MHz, CDCl3, 294 K): δ 8.28˜8.16 (m, 3H), 7.91˜7.83 (m, 3H), 7.72 (s, 1H), 7.70 (d, 1H), 7.45 (s, 1H), 7.15 (t, 1H), 5.69˜5.66 (m, 2H), 1.37 (s, 9H), 0.17 (s, 9H), 0.08 (s, 9H).

### Example 5: Preparation of Organometallic Compound DFTIr(Miaz)

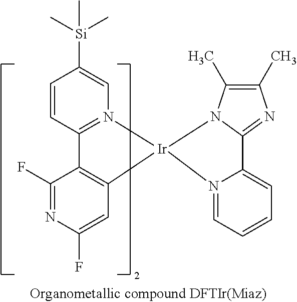

The dimer A (0.5 g, 0.33 mmol), ligand

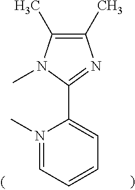

(299 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(Miaz) was obtained. The synthesis pathway of the above reaction was as follows:

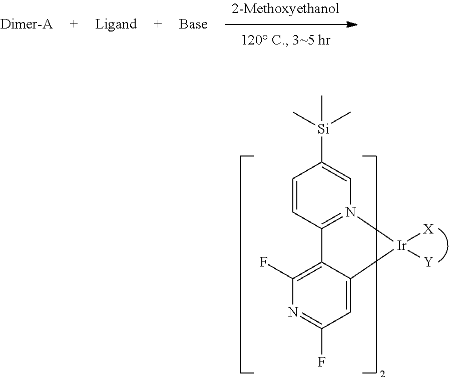

The physical measurement of the compound DFTIr(Miaz) is listed below: 1H NMR (200 MHz, CDCl3, 294 K): δ 8.35˜8.22 (m, 3H), 7.95˜7.80 (m, 3H), 7.70 (d, 1H), 7.65 (s, 1H), 7.50 (s, 1H), 7.35 (s, 1H), 7.10 (t, 1H), 6.61 (s, 1H), 3.51 (s, 3H), 3.12 (s, 3H), 0.15 (s, 9H), 0.08 (s, 9H).

### Example 6: Preparation of Organometallic Compound DFTIr(acac)

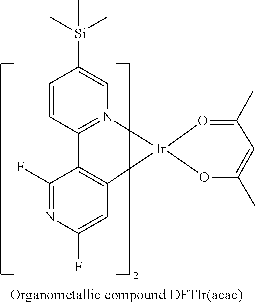

The dimer A (0.5 g, 0.33 mmol), ligand

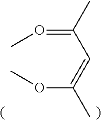

(133 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(acac) was obtained. The synthesis pathway of the above reaction was as follows:

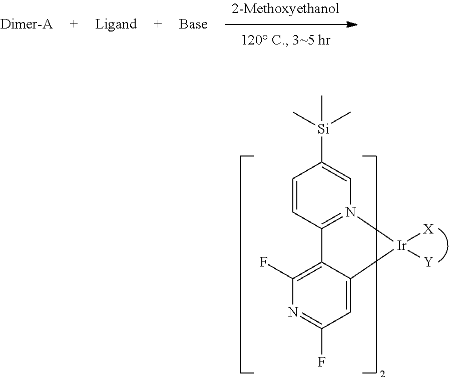

The physical measurement of the compound DFTIr(acac) is listed below: 1H NMR (200 MHz, CDCl3, 294 K): δ 8.45 (s, 2H), 8.22 (d, 2H), 7.97 (d, 2H), 5.65 (t, 2H), 5.33 (s, 1H), 1.85 (s, 6H), 0.35 (s, 18H).

### Example 7: Preparation of Organometallic Compound DFTIr(tmd)

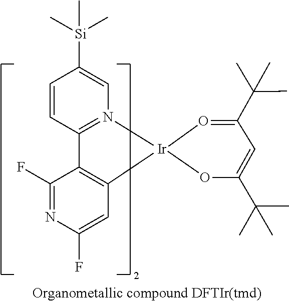

The dimer A (0.5 g, 0.33 mmol), ligand

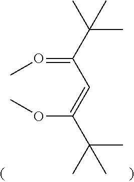

(245 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(tmd) was obtained. The synthesis pathway of the above reaction was as follows:

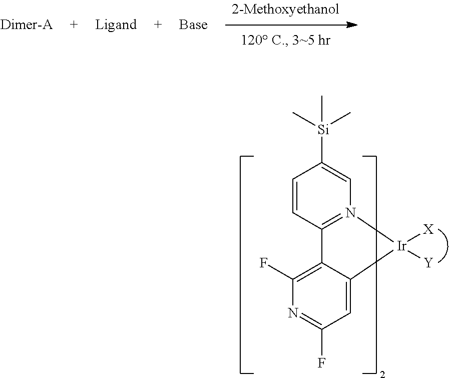

The physical measurement of the compound DFTIr(tmd) is listed below: 1H NMR (200 MHz, CDCl3, 294 K): δ 8.31 (s, 2H), 8.17 (d, 2H), 7.90 (d, 2H), 5.81 (t, 2H), 5.613 (s, 1H), 0.84 (s, 18H), 0.29 (s, 18H).

### Example 8: Preparation of Organometallic Compound DFTIr(hf)

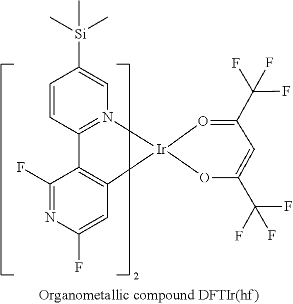

The dimer A (0.5 g, 0.33 mmol), ligand

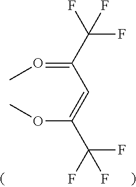

(277 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(hf) was obtained. The synthesis pathway of the above reaction was as follows:

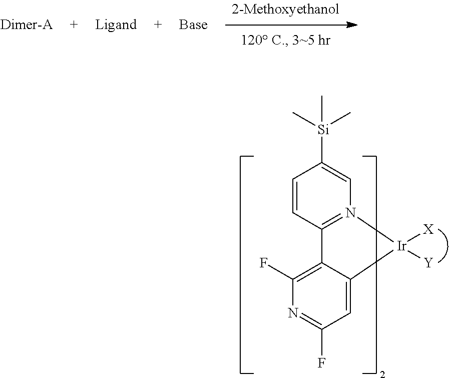

The physical measurement of the compound DFTIr(hf) is listed below: 1H NMR (200 MHz, CDCl3, 294 K): δ 8.27 (d, 2H), 8.25 (s, 2H), 8.06 (d, 2H), 6.09 (s, 1H), 5.60 (t, 2H), 0.34 (s, 18H).

### Example 9: Preparation of Organometallic Compound DFTIr(dbm)

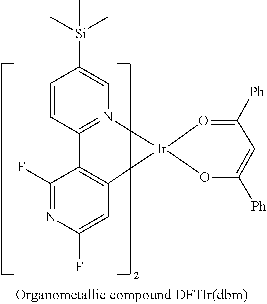

The dimer A (0.5 g, 0.33 mmol), ligand

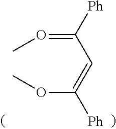

(311 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DFTIr(dbm) was obtained. The synthesis pathway of the above reaction was as follows:

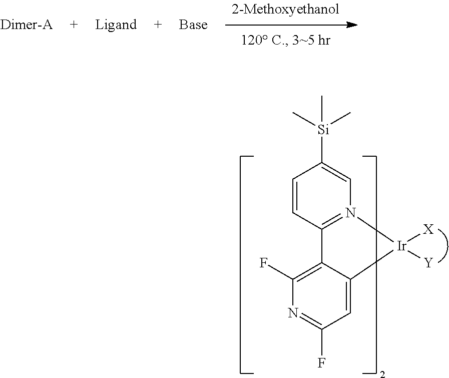

The physical measurement of the compound DFTIr(dbm) is listed below: 1H NMR (200 MHz, CDCl₃, 294 K): δ8.56 (s, 2H), 8.22 (d, 2H), 7.92 (d, 2H), 7.80 (d, 4H), 7.47˜77.31 (m, 6H), 6.67 (s, 1H), 5.76 (t, 2H), 0.15 (s, 18H).

The photoluminescence (PL) emission spectra of the organometallic compounds (a series of DFTIr) of the disclosure

As shown in Table 2, the organometallic compounds of the disclosure having a stronger electron-withdrawing ligand (such as: pic, taz or taz2) can exhibit a blue-shifted emission and serve as blue phosphorescent material. For example, the PL spectra (452 nm) of the organometallic compound DFTIr(pic) can have a 23 nm blue-shift in comparison with the PL spectra (475 nm) of the conventional phosphorescent material FIr(pic).

TABLE 2

| DFTIr(acac) | DFTIr(pic) | DFTIr(taz) | DFTIr(taz2) |
|---|---|---|---|
| 465 nm | 452 nm | 447 nm | 452 nm |

### Example 10: Preparation of Organometallic Compound DFTIr

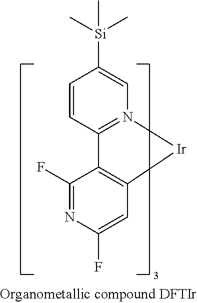

The dimer A (0.37 g, 0.25 mmol), ligand

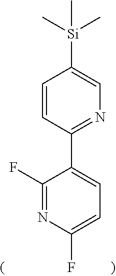 [SMILES: C[Si](C)(C)c1ccc(-c2ccc(F)nc2F)nc1]

(200 mg 0.25 mmol), AgOCOCF₃ (160 mg, 0.75 mmol) and diphenyl ether (5 mL) were added into a 10 mL flask. After removing the moisture and the air therein, the reaction bottle was heated to 165° C. under nitrogen atmosphere and keep reacting for two hours. After cooling down to room temperature, purified by column chromatography ((SiO₂, EA/Hexane=1/8), Compound DFTIr was obtained. The synthesis pathway of the above reaction was as follows:

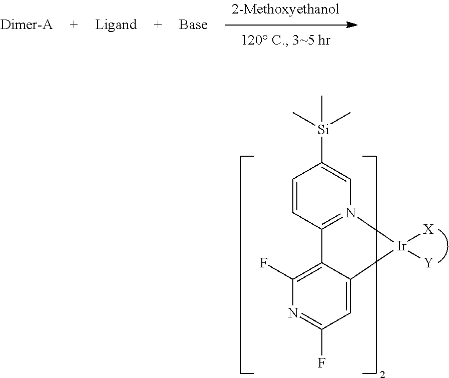

The physical measurement of the compound DFTIr is listed below: 1H NMR (200 MHz, CDCl₃, 294 K): δ 8.33 (d, 1H), 8.21 (t, 2H), 8.05˜7.77 (m, 5H), 7.31 (s, 1H), 6.43 (t, 1H), 5.92 (t, 1H), 5.70 (s, 1H), 0.14 (s, 9H), 0.12 (s, 9H), 0.05 (s, 9H).

The photoluminescence (PL) emission spectra of the organometallic compounds (a series of DFTIr) of the disclosure

The organometallic compound DFTIr have a property of the PL spectra (448 nm) and the half maximum wavelength (57 nm), that is, it is a high colorimetric purity and serves as blue phosphorescent material. Thus, it can be used for lighting application of color temperature adjusting and display application of pure blue light emission.

The sublimation purification of the organometallic compounds (a series of DFTIr) of the disclosure

The organometallic compounds (a series of DFTIr) of the disclosure have a sublimation yield that is close to 100% due to their good thermal stability. The devices in Examples of the disclosure show high yield as compared with the conventional phosphorescent material FIr(pic) (its yield is about 50%). For example, after the compound DFTIr(acac) was purified by a sublimation process, there's almost nothing in the tube after sublimation and almost all the compound DFTIr(acac) was sublimated into the collection tube.

### Example 11: Preparation of Organometallic Compound DMTIr(taz)

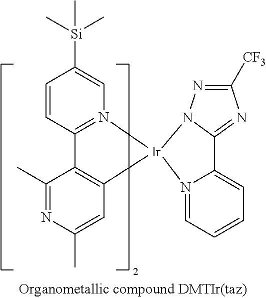

Firstly, after a 100 mL double-neck bottle was dried to remove the moisture and the air several times, 2,5-dibromopyridine (1 g, 4.22 mmol) and dehydrated ether (40 mL) were dropwise added into the bottle under nitrogen atmosphere. Next, after cooling to −78° C. and temperature equilibrating, n-BuLi (3 mL, 4.64 mmol) was dropwise added into the reaction bottle and subjected to reaction at −78° C. for 1 hours, and then TMSCl (0.65 mL, 5 mmol) was added thereto. The reaction was then warmed to room temperature and the reaction mixture was extracted three times using ethyl acetate (EA) and water as the extraction solvent. Next, an organic phase was separated and concentrated, and then purified by column chromatography (SiO₂, EA/Hexane=1/40), 2-bromo-5-trimethylsilylpyridine was obtained. The synthesis pathway of the above reaction was as follows:

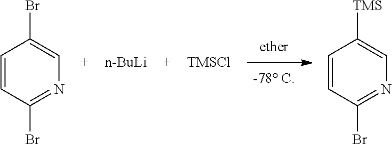 [SMILES: "TMSCl" ; "n-BuLi" ; Brc1ccc(Br)nc1 ; C[Si](C)(C)c1ccc(Br)nc1]

Next, 2-Bromo-5-trimethylsilylpyridine (0.7 g, 3 mmol), 2,6-dimethylpyridine-3-bromic acid (0.52 g, 3.3 mmol), K₂CO₃ (0.4 g, 1 mmol), dimethoxyethane (20 mL), water (10 mL) and tetrakis(triphenylphosphine)palladium Pd(PPh₃)₄ (0.17 g, 0.15 mmol)) were added into a 100 mL double-neck bottle. After the reaction bottle was dried to remove the moisture and the air therein, the reaction bottle was heated to reflux under nitrogen atmosphere and keep refluxing overnight. After cooling to room temperature, the reaction mixture was neutralized to weak alkalinity (pH 8 to 10) with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/40), and compound (B) was obtained. The synthesis pathway of the above reaction was as follows:

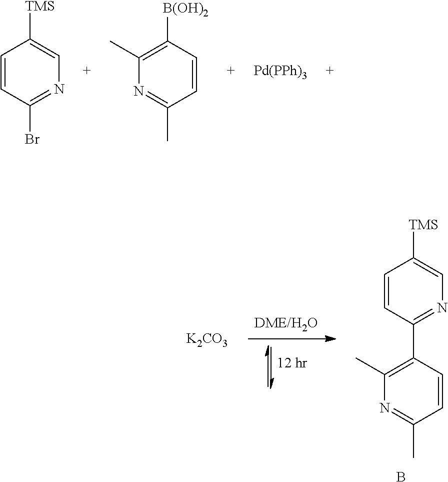

The compound B (1.7 g, 6.6 mmol), IrCl₃ (0.89 g, 3 mmol), 2-methoxyethanol (24 mL) and water (8 mL) were added into a 100 mL flask. After removing the moisture and the air therein, the reaction bottle was heated to 120° C. under nitrogen atmosphere and keep reacting overnight. After cooling to room temperature, water was added into the reaction mixture to induce precipitation. Then, the precipitate was purified and dried under vacuum, and, a dimer B was obtained. The synthesis pathway of the above reaction was as follows:

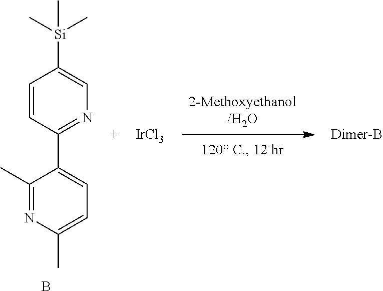

The dimer B (0.5 g, 0.33 mmol), ligand

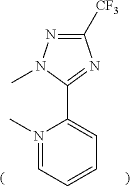

(285 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DMTIr(taz) was obtained. The synthesis pathway of the above reaction was as follows:

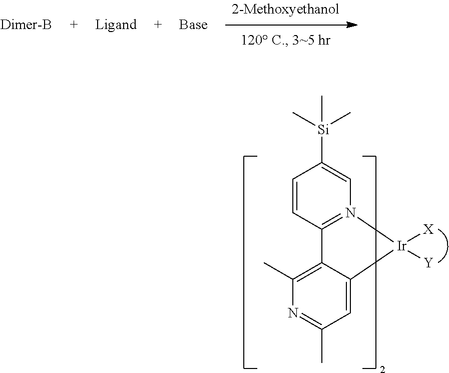

The physical measurement of the compound DMTIr(taz) is listed below: 1H NMR (200 MHz, CDCl₃, 294 K): δ8.31 (d, 1H), 8.11 (d, 1H), 8.04 (d, 1H), 7.91 (t, 1H), 7.84˜7.78 (m, 3H), 7.69 (d, 1H), 7.50 (s, 1H), 7.22 (t, 1H), 5.92 (s, 1H), 5.83 (s, 1H), 2.86 (s, 6H), 2.29 (s, 3H), 2.23 (s, 3H), 0.15 (s, 9H), 0.04 (s, 9H).

### Example 12: Preparation of Organometallic Compound DMTIr(iaz)

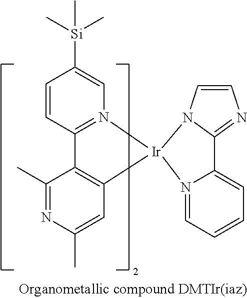

The dimer B (0.5 g, 0.33 mmol), ligand

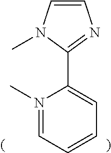

(193 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DMTIr(iaz) was obtained. The synthesis pathway of the above reaction was as follows:

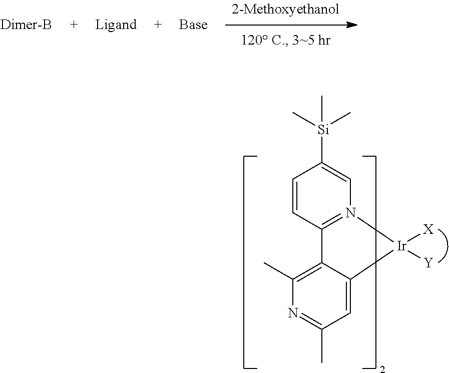

The physical measurement of the compound DFMIr(iaz) is listed below: 1H NMR (200 MHz, CDCl₃, 294 K): δ 8.29˜8.17 (m, 3H), 7.88˜7.77 (m, 3H), 7.67 (d, 1H), 7.62 (s, 1H), 7.52 (s, 1H), 7.32 (s, 1H), 7.06 (t, 1H), 6.61 (s, 1H), 5.80 (t, 1H), 5.68 (t, 1H), 0.13 (s, 9H), 0.09 (s, 9H).

### Example 13: Preparation of Organometallic Compound DMTIr(pic)

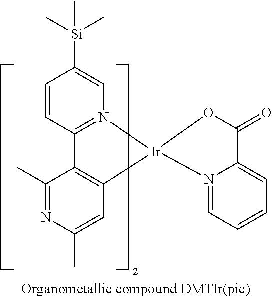

The dimer B (0.5 g, 0.33 mmol), ligand

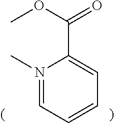

(193 mg 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DMTIr(pic) was obtained. The synthesis pathway of the above reaction was as follows:

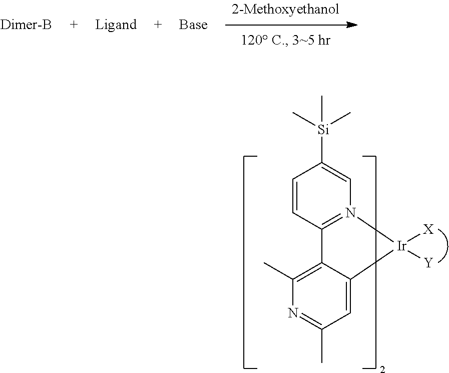

The physical measurement of the compound DMTIr(pic) is listed below: 1H NMR (200 MHz, CDCl₃, 294 K): δ 8.87 (s, 1H), 8.33 (d, 1H), 8.10 (dd, 2H), 7.99˜7.85 (m, 3H), 7.71 (d, 1H), 7.45˜7.39 (m, 2H), 6.02 (s, 1H), 5.78 (s, 1H), 2.92 (s, 3H), 2.86 (s, 3H), 2.26 (s, 3H), 2.23 (s, 3H), 0.31 (s, 9H), 0.07 (s, 9H).

### Example 14: Preparation of Organometallic Compound DMTIr(acac)

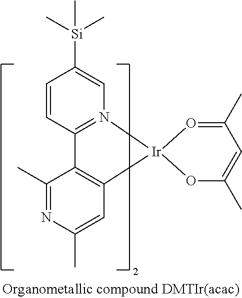

The dimer B (0.5 g, 0.33 mmol), ligand

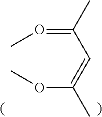

(133 mg, 1.33 mmol), trimethylamine (0.1 mL, 1.33 mmol) and 2-methoxyethanol (5 mL) were added into a 10 mL flask. After removing the moisture and the air therein, the reaction bottle was heated to 120° C. under nitrogen atmosphere and keep reacting for three hours. After cooling to room temperature, water was added into the result to induce precipitation. The precipitate was collected and washed with water and hexane, and then dissolved into CH₂Cl₂. The result was extracted three times with CH₂Cl₂ and water as the extraction solvent. Next, an organic phase was separated and concentrated, and then purified by column chromatography (SiO₂, EA/Hexane=1/40), Compound DMTIr(pic) was obtained. The synthesis pathway of the above reaction was as follows:

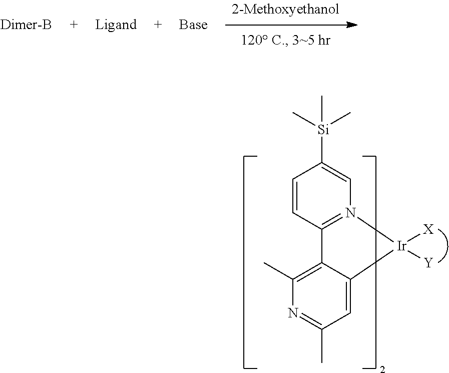

The physical measurement of the compound DMTIr(pic) is listed below: 1H NMR (200 MHz, CDCl₃, 294 K): δ 8.57 (s, 2H), 8.07 (d, 2H), 7.89 (d, 2H), 5.90 (s, 2H), 5.24 (s, 1H), 2.84 (s, 6H), 2.19 (s, 6H), 1.79 (s, 6H), 0.33 (s, 18H).

### Comparative Example 1: Preparation of Organometallic Compound DFTIr(acac)-O

Firstly, 2,6-difluoropyrdine (12.5 g, 110.0 mmol), acetic acid (100 mL) and 30% hydrogen peroxide (15.0 g, 440 mmol) were added into a 100-mL double-neck bottle and heated to 70° C. under nitrogen atmosphere and left to react for ten hours. After the reaction was completed, the reaction mixture was neutralized to weak alkalinity with saturated sodium hydrogen carbonate (NaHCO₃) aqueous solution. The mixture was extracted with ethyl acetate (EA) and water three times. Next, the collected organic phase was dried and filtered. After draining with a rotary concentrator, a crude product was obtained. The synthesis pathway of the above reaction was as follows:

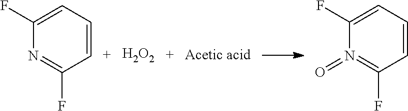

Next, the starting material (2,6-difluoropyridine N-oxide, 6 g, 45 mmol) and dehydrated THF (150 mL) were added into a 250-mL double-neck bottle. After drying several times to remove oxygen, nitrogen gas was conducted thereinto. Next, after cooling to −78° C. and temperature equilibration, LDA (22 g, 55 mmol) was dropwise added into the bottle using a syringe and subjected to react at −78° C. for 1 hour, and then water was added thereto to terminate the reaction. The pH of the reaction mixture was adjusted to weak acidity with 1N HCl. The mixture was then extracted three times using ethyl acetate (EA) and water as the extraction solvent. Next, the collected organic phase was dried and filtered. After draining with a rotary concentrator, a crude product was obtained. The synthesis pathway of the above reaction was as follows:

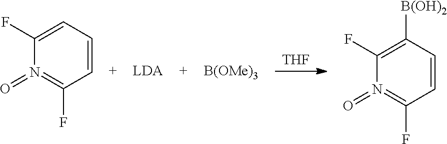

Next, 2-bromo-5-trimethylsilylpyridine (0.7 g, 3 mmol), 2,6-difluoropyridine-3-bromic acid having N-oxide (0.58 g, 3.3 mmol), K₂CO₃ (0.4 g, 1 mmol), dimethoxyethane (20 mL), water (10 mL) and catalytic amount of tetrakis(triphenylphosphine)palladium (Pd(PPh₃)₄) were added into a 100-mL double-neck bottle. After the bottle was dried several times to remove moisture and oxygen therein, the bottle was heated to reflux under nitrogen atmosphere and to keep refluxing overnight. After cooling to room temperature, the reaction mixture was neutralized to weak alkalinity with saturated sodium hydrogen carbonate (NaHCO₃) aqueous solution, and then the mixture was extracted with ethyl acetate (EA) and water three times. Next, the collected organic phase was dried and filtered. After draining with a rotary concentrator, the results were purified by column chromatography (SiO₂, EA/Hexane=1/10), and a compound A-O was obtained. The synthesis pathway of the above reaction was as follows:

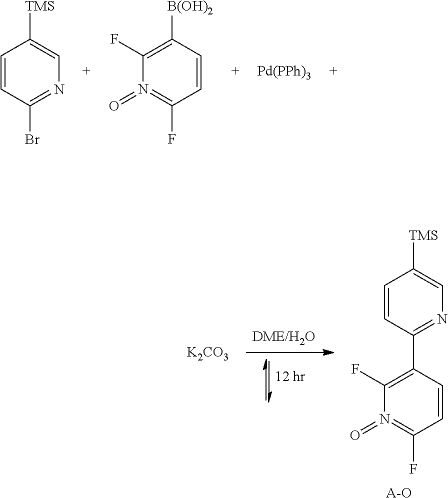

Next, the compound A-O (1.8 g, 6.6 mmol), IrCl₃ (0.89 g, 3 mmol), 2-methoxyethanol (24 mL) and water (8 mL) were added into a 100-mL double-neck bottle. After drying several times to remove moisture and oxygen therein, the bottle was heated to 120° C. under nitrogen atmosphere and left to react overnight. After cooling to room temperature, water was added into the reaction mixture to produce precipitate. The resulting solution was then filtered. The obtained solid was washed with water and n-hexane. The solid was then collected and dried under vacuum, and then Dimer-A-O was obtained. The synthesis pathway of the above reaction was as follows:

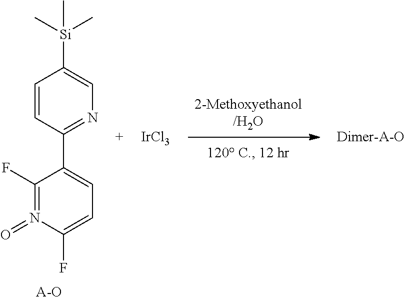

The Dimer-A-O (0.57 g, 0.33 mmol), ligand

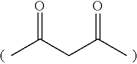

(133 mg, 1.33 mmol), weak base (0.1 mL, 1.33 mmol) and 2-methoxyethanol (5 mL) were added into a 10-mL round-bottom bottle. After drying several times to remove moisture and oxygen therein, the bottle was heated to 120° C. under nitrogen atmosphere and left to react for three to five hours. After cooling to room temperature, water was added into the results to induce precipitation. The resulting solution was then filtered. The obtained solid was washed with water and n-hexane. The solid was collected and dissolved by CH₂Cl₂. The results were extracted three times with CH₂Cl₂ and water as the extraction solvent. Next, the collected organic phase was dried and filtered. After draining with a rotary concentrator, the results were purified by column chromatography. The organometallic complex DFTIr(acac)-O of this comparative example was obtained. The synthesis pathway of the above reaction was as follows:

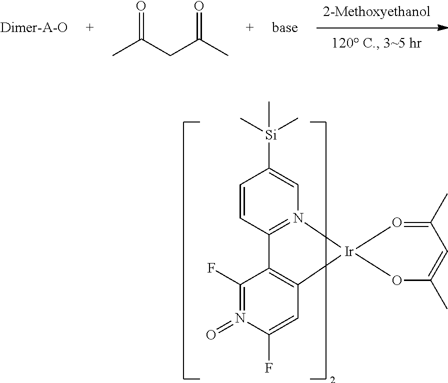

The compound DFTIr(acac)-O was analyzed using nuclear magnetic resonance spectroscopy. The spectral information thereof was as follows: ¹H NMR (200 MHz, CDCl₃, 294 K): 8.41 (d, 2H), 8.16 (d, 2H), 7.81 (d, 2H), 5.62 (t, 2H), 5.25 (s, 1H), 1.80 (s, 6H), 0.34 (s, 18H).

### Example 15: Fabrication of the Organic Light-Emitting Device (1) (Dry Process)

A glass substrate with an indium tin oxide (ITO) film with a thickness of 110 nm was provided and then washed with a cleaning agent, acetone, and isopropanol with ultrasonic agitation. After drying with nitrogen flow, the ITO film was subjected to a UV/ozone treatment for 30 min. Next, TAPC(1,1-bis[4-[N, N′-di (p-tolyl)amino]phenyl]cyclobexane, with a thickness of 40 nm), 26DCzPPY doped with the organometallic compound DFTIr(acac) of Example 6 (the ratio between 26DCzPPY and the organometallic compound DFTIr(acac) was 10:1, with a thickness of 10 nm), TmPyPB (1,3,5-tri(p-pyrid-3-yl-phenyl)benzene, with a thickness of 50 nm), LiF (with a thickness of 0.8 nm), and Al (with a thickness of 120 nm) were subsequently deposited on the ITO film at 10⁻⁶ torr, obtaining the organic light-emitting device (1). The materials and layers formed therefrom are described in the following: ITO (150 nm)/TAPC (40 nm)/26DCzPPy: organometallic DFTIr(acac)(10%)(10 nm)/TmPyPB (50 nm)/LiF (0.8 nm)/Al (120 nm)

Next, the optical properties (such as current efficiency (cd/A), power efficiency (lm/W), emission wavelength (nm), and C.I.E coordinates (x, y)) of the light-emitting device (1), as described in Example 15, were measured by a spectra colorimeter PR650 (purchased from Photo Research Inc.) and a luminance meter LS110 (purchased from Konica Minolta). The results are shown in Table 3

### Example 16: Fabrication of the Organic Light-Emitting Device (2) (Dry Process)

Example 16 was performed in the same manner as in Example 15 except that TATC was substituted for 26DCzPPy (TCTA doped with the organometallic compound DFTIr(acac) of Example 6), obtaining the organic light-emitting device (2). The materials and layers formed therefrom are described in the following: ITO (150 nm)/TAPC (40 nm)/TCTA: organometallic DFTIr(acac)(10%)(10 nm)/TmPyPB (50 nm)/LiF (0.8 nm)/Al (120 nm)

Next, the optical properties (such as current efficiency (cd/A), power efficiency (lm/W), emission wavelength (nm), and C.I.E coordinates (x, y)) of the light-emitting device (1), as described in Example 15, were measured by a spectra colorimeter PR650 (purchased from Photo Research Inc.) and a luminance meter LS110 (purchased from Konica Minolta). The results are shown in Table 3

### Comparative Example 2: Fabrication of a Traditional Organic Light-Emitting Device (Dry Process)

Comparative Example 2 was performed in the same manner as in Example 15 except that mCP doped with FK306

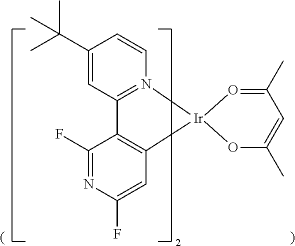

was substituted for 26DCzPPY doped with the organometallic compound DFTIr(acac), obtaining the traditional organic light-emitting device.

Next, the optical properties (such as current efficiency (cd/A), power efficiency (lm/W), emission wavelength (nm), and C.I.E coordinates (x, y)) of the light-emitting device (1), as described in Example 15, were measured by a spectra colorimeter PR650 (purchased from Photo Research Inc.) and a luminance meter LS110 (purchased from Konica Minolta). The results are shown in Table 3

TABLE 3

| | | current | power | | |
|---|---|---|---|---|---|
| | | efficiency | efficiency | λmax | C.I.E coordinate |
| | Light-emitting layer | (cd/A) | (lm/W) | (nm) | (x, y) |
| Comparative | mCP:FK306 | 21.5 | 16.1 | 454 | (0.16, 0.25) |
| Example 2 | | | | | |
| Example 15 | 26DCzPPy:DFTIr(acac) | 25.2 | 18.7 | 464 | (0.15, 0.25) |
| Example 16 | TCTA:DFTIr(acac) | 22.0 | 17.2 | 464 | (0.15, 0.25) |

In accordance with Table 3, in the examples, the optical properties of the organic light emitting diodes fabricated with host material 26DCzPPy or TCTA combined with the dopant DFTIr(acac) are shown in Table 3. Particularly, the current efficiency of the organic light emitting diode (1) fabricated with host material 26DCzPPy combined with the dopant DFTIr(acac) (25.2 cd/A) was about 16% higher than that of the organic light-emitting diode (2) fabricated with host material TCTA combined with the dopant DFTIr(acac) (22.0 cd/A) (measured at a brightness of 1000 Cd/m²).

### Example 17

The optical properties of the organometallic compounds of the disclosure

As shown in Table 4, in the example, the optical properties of organic light emitting diodes fabricated by host material 26DCzPPy combined with various dopants was measured, because the organic light emitting diode (1) fabricated with host material 26DCzPPy exhibited higher optical properties than the organic light emitting diode (2). Due to the organometallic compound DFTIr(tmd) showing great steric hindrance, the optical properties and light of the organic light emitting diode with it was similar to that of the organic light emitting diode with DFTIr(acac). The organometallic compounds having a stronger electron-withdrawing ligand (such as: pic, taz or taz2) had a 12-16 nm blue-shift, but the luminescence efficiencies of the organic light emitting diodes with these dopants were over 10 lm/W. The organometallic compound DMTIr(acac) emitted bluish green light, but the luminescence efficiency of the organic light emitting diode with that achieved 57.2 lm/W.

TABLE 4

| | current | | | |
|---|---|---|---|---|
| | efficiency | power efficiency | λmax | C.I.E coordinate |
| | (cd/A) | (lm/W) | (nm) | (x, y) |
| DFTIr(acac) | 25.2 | 18.7 | 464 | (0.15, 0.25) |
| DFTIr(acac)-O | 26.5 | 19.6 | 468 | (0.17, 0.33) |
| DFTIr(tmd) | 24.9 | 17.4 | 464 | (0.15, 0.25) |
| DFTIr(pic) | 18.2 | 12.0 | 452 | (0.15, 0.23) |
| DFTIr(taz) | 20.2 | 14.5 | 448 | (0.15, 0.22) |
| DFTIr(taz2) | 19.7 | 14.1 | 452 | (0.15, 0.23) |
| DMTIr(acac) | 65.3 | 57.2 | 492 | (0.19, 0.52) |
| DMTIr(pic) | 30.2 | 22.4 | 476 | (0.18, 0.37) |

### Example 18: Fabrication of the Organic Light-Emitting Device (3) (Wet Process)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, PEDOT(poly(3,4)-ethylendioxythiophen): PSS(e-polystyrenesulfonate) was coated on the ITO film by a blade and spin coating process (with a rotation rate of 2000 rpm) and baked at 130° C. for 10 min to form a PEDOT:PSS film serving as a hole injection layer (with a thickness of 40 nm). Next, a composition was used for forming a light-emitting layer coated on the PEDOT:PSS film by a blade coating process and baked at 100° C. for 40 min to form the light-emitting layer (with a thickness of 30 nm). The composition used for forming a light-emitting layer includes mCP and the organometallic compound DFTIr(acac), wherein the weight ratio of mCP to the organometallic compound DFTIr(acac) was 4:1, dissolved in chlorobenzene. Next, TmPyPB (1,3,5-tri(p-pyrid-3-yl-phenyl)benzene was coated on the light-emitting layer by a spin coating process to form a TmPyPB film (with a thickness of 45 nm). Next, LiF (with a thickness of 1 nm), and Al (with a thickness of 100 nm) were subsequently formed on the TmPyPB film at 1×10 Pa, obtaining the organic light-emitting device (3) after encapsulation. The materials and layers formed therefrom are described in the following:

ITO (150 nm)/PEDOT:PSS (40 nm)/mCP: organometallic compound DFTIr(acac) (30 nm)/TmPyPB (45 nm)/LiF (1 nm)/Al (100 nm)

Next, the optical properties (such as current efficiency (cd/A), power efficiency (lm/W), emission wavelength (nm), and C.I.E coordinates (x, y)) of the organic light-emitting device (3) were measured by a spectra colorimeter PR650 (purchased from Photo Research Inc.) and a luminance meter LS110 (purchased from Konica Minolta). The results are shown in Table 5.

### Example 19: Fabrication of the Organic Light-Emitting Device (4) (Wet Process)

Example 19 was fabricated in the same manner as in Example 18 except that TATC was substituted for mCP (TCTA doped with the organometallic compound DFTIr(acac) of Example 6), obtaining the organic light-emitting device (4). The materials and layers formed therefrom are described in the following:

ITO (150 nm)/PEDOT:PSS (40 nm)/TCTA: organometallic compound DFTIr(acac) (30 nm)/TmPyPB (45 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (4) were measured by a spectra colorimeter PR650 (purchased from Photo Research Inc.) and a luminance meter LS110 (purchased from Konica Minolta). The results are shown in Table 5

### Example 20: Fabrication of the Organic Light-Emitting Device (5) (Wet Process)

Example 20 was fabricated in the same manner as in Example 19 except that the organometallic compound DFTIr(tmd) was substituted for the organometallic compound DFTIr(acac) (TCTA doped with the organometallic compound DFTIr(tmd) of Example 7), obtaining the organic light-emitting device (5). The materials and layers formed therefrom are described in the following:

ITO (150 nm)/PEDOT:PSS (40 nm)/TCTA: organometallic compound DFTIr(tmd) (30 nm)/TmPyPB (45 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (5) were measured by a spectra colorimeter PR650 (purchased from Photo Research Inc.) and a luminance meter LS110 (purchased from Konica Minolta). The results are shown in Table 5

### Example 21: Fabrication of the Organic Light-Emitting Device (6) (Wet Process)

Example 21 was fabricated in the same manner as in Example 19 except that the organometallic compound DMTIr(acac) was substituted for the organometallic compound DFTIr(acac) (TCTA doped with the organometallic compound DMTIr(acac) of Example 14), obtaining the organic light-emitting device (6). The materials and layers formed therefrom are described in the following:

ITO (150 nm)/PEDOT:PSS (40 nm)/TCTA: organometallic compound DMTIr(acac) (30 nm)/TmPyPB (45 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (6) were measured by a spectra colorimeter PR650 (purchased from Photo Research Inc.) and a luminance meter LS110 (purchased from Konica Minolta). The results are shown in Table 5

### Example 22: Fabrication of the Organic Light-Emitting Device (7) (Wet Process)

Example 22 was fabricated in the same manner as in Example 19 except that the organometallic compound DMTIr(pic) was substituted for the organometallic compound DFTIr(acac) (TCTA doped with the organometallic compound DMTIr(pic) of Example 13), obtaining the organic light-emitting device (7). The materials and layers formed therefrom are described in the following:

ITO (150 nm)/PEDOT:PSS (40 nm)/TCTA: organometallic compound DMTIr(pic) (30 nm)/TmPyPB (45 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (6) were measured by a spectra colorimeter PR650 (purchased from Photo Research Inc.) and a luminance meter LS110 (purchased from Konica Minolta). The results are shown in Table 5

### Comparative Example 3: Fabrication of a Traditional Organic Light-Emitting Device (Wet Process)

Comparative Example 3 was fabricated in the same manner as in Example 19 except that TCAC doped with the organometallic compound FTIr(pic) was substituted for TCAC doped with the organometallic compound DFTIr(acac), obtaining the traditional organic light-emitting device.

Next, the optical properties (such as current efficiency (cd/A), power efficiency (lm/W), emission wavelength (nm), and C.I.E coordinates (x, y)) of the traditional light-emitting device were measured by a spectra colorimeter PR650 (purchased from Photo Research Inc.) and a luminance meter LS110 (purchased from Konica Minolta). The results are shown in Table 5

TABLE 5

| | | current | power | | C.I.E |
|---|---|---|---|---|---|
| | OLED | efficiency | efficiency | λmax | coordinate |
| | device | (cd/A) | (lm/W) | (nm) | (x, y) |
| Example 18 | device (3) | 14.3 | 9.8 | 464 | (0.16, 0.28) |
| Example 19 | device (4) | 14.2 | 10.7 | 464 | (0.16, 0.29) |
| Example 20 | device (5) | 13.3 | 10.9 | 464 | (0.16, 0.29) |
| Example 21 | device (6) | 34.1 | 30.5 | 492 | (0.20, 0.56) |
| Example 22 | device (7) | 21.2 | 17.1 | 476 | (0.18, 0.37) |
| Comparative | | — | 15.0 | 475 | (0.18, 0.39) |
| Example 3 | | | | | |

During the formation of the light-emitting device via a wet process, it showed that the organometallic compounds (a series of DFTIr) of the disclosure exhibited high solubility (the solution has a solid content that is more than 4 wt %), the organometallic compounds of the disclosure can be uniformly mixed with the TCTA or mCP. The luminescence efficiency of the organic light emitting diode (4) with the dopant DFTIr(acac) achieved 10.7 lm/W, and the luminescence efficiency of the organic light emitting diode (5) with the dopant DFTIr(tmd) achieved 10.9 lm/W (measured at a brightness of 1000 Cd/m²), that is, the devices in Examples of the disclosure showed high driving durability. Moreover, the luminescence efficiency of the organic-light emitting diode (7) with the dopant DMTIr(pic) of the disclosure fabricated via the wet process is 17.1 lm/W (measured at a brightness of 1000 Cd/m²), that is, it was about 14% higher than that of the organic light-emitting diode with the dopant FTIr(pic).

### Example 23: Fabrication of the Organic Light-Emitting Device (8) (Dry Process)

A glass substrate with an indium tin oxide (ITO) film with a thickness of 110 nm was provided and then washed with a cleaning agent, acetone, and isopropanol with ultrasonic agitation. After drying with nitrogen flow, the ITO film was subjected to a UV/ozone treatment for 30 min. Next, TAPC(1,1-bis[4-[N, N′-di (p-tolyl)amino]phenyl]cyclohexane, with a thickness of 35 nm), TCTA doped with the organometallic compound DFTIr(tmd) (the ratio between TATC and the organometallic compound DFTIr(tmd) was 1:0.05, with a thickness of 6 nm), 26DCzPPY doped with the organometallic compound DFTIr(tmd) (the ratio between 26DCzPPY and the organometallic compound DFTIr(tmd) was 1:0.06, with a thickness of 6 nm), TmPyPB (1,3,5-tri(p-pyrid-3-yl-phenyl)benzene, with a thickness of 110 nm), LiF (with a thickness of 1 nm), and Al (with a thickness of 100 nm) were subsequently formed on the ITO film at 10⁻⁶ torr, obtaining the organic light-emitting device (8). The materials and layers formed therefrom are described in the following:

ITO (150 nm)/TAPC (35 nm)/TATC: organometallic DFTIr(tmd)(5%)(6 nm)/26DCzPPy: organometallic DFTIr(tmd)(6%)(6 nm)/TmPyPB (110 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (8), as described in Example 15, were measured by a spectra colorimeter PR650 (purchased from Photo Research Inc.) and a luminance meter LS110 (purchased from Konica Minolta). The results are shown in Table 3

### Example 24: Fabrication of the Organic Light-Emitting Device (9) (Dry Process)

Example 24 was fabricated in the same manner as in Example 23 except that the organometallic compound DFTIr(acac) was substituted for the organometallic compound DFTIr(tmd), obtaining the organic light-emitting device (9). The materials and layers formed therefrom are described in the following:

ITO (150 nm)/TAPC (35 nm)/TATC: organometallic DFTIr(acac)(6%)(6 nm)/26DCzPPy: organometallic DFTIr(acac)(8%)(6 nm)/TmPyPB (110 nm)/LiF (1 nm)/Al (100 nm)

Next, the optical properties (such as current efficiency (cd/A), power efficiency (lm/W), emission wavelength (nm), and C.I.E coordinates (x, y)) of the light-emitting device (9) were measured by a spectra colorimeter PR650 (purchased from Photo Research Inc.) and a luminance meter LS110 (purchased from Konica Minolta). The results are shown in Table 6

TABLE 6

| | | current | power | | C.I.E |
|---|---|---|---|---|---|
| | OLED | efficiency | efficiency | λmax | coordinate |
| | device | (cd/A) | (lm/W) | (nm) | (x, y) |
| Comparative | | 21.5 | 16.1 | 454 | (0.16, 0.25) |
| Example 2 | | | | | |
| Example 23 | device (8) | 32.4 | 30.2 | 464 | (0.15, 0.25) |
| Example 24 | device (9) | 29.5 | 27.2 | 464 | (0.15, 0.25) |
| Comparative | | — | 15.0 | 475 | (0.18, 0.39) |
| Example 3 | | | | | |

As can be apparently seen from the above results, with dual light emitting layers, the luminescence efficiency of the organic light emitting diode (9) with the dopant DFTIr(acac) achieved 27.2 lm/W. The luminescence efficiency of the organic light emitting diode (8) with the dopant DFTIr(tmd) achieved 30.2 lm/W, that is, it was about 1.88 times of the organic light-emitting diode with the dopant FK306 in Comparative Example 2. In addition, the luminescence efficiency of the organic light emitting diode with dual light emitting layers of the disclosure is better than that of organic light emitting diode with single light emitting layer in Comparative Example 3.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organometallic compound having a structure represented by Formula (I): 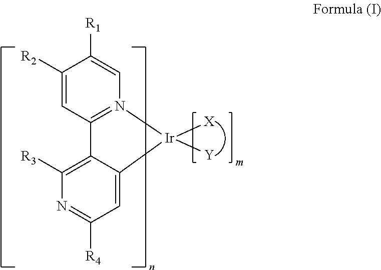
wherein, one of R₁ and R₂ is trimethylsilyl (TMS) and the other is hydrogen, at least one of R₃ and R₄ is fluorine or C₁₋₆ alkyl, or one of R₃ and R₄ is fluorine and the other is C₁₋₆ alkyl, 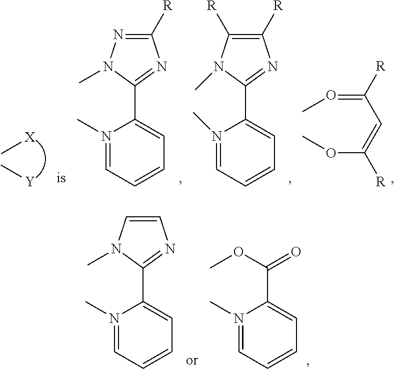
R is CH₃, CH₂CH₃, CH(CH₃)₂, C(CH₃)₃, CF₃, CHF₂, C₃F₈ or phenyl, and n is 2 or 3, and m is 0 or 1, wherein n+m=3.

2. The organometallic compound as claimed in claim 1, wherein the organometallic compound has a structure represented by Formula (II): 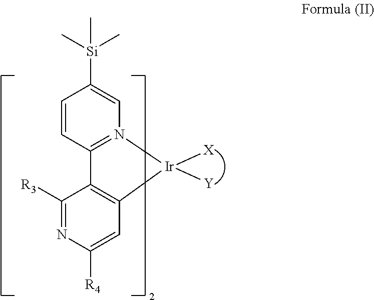
wherein R₅ is fluorine or C₁₋₆ alkyl, 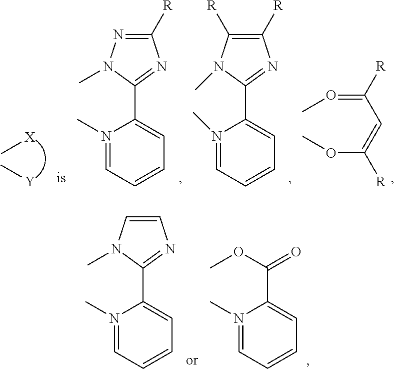
R is CH₃, CH₂CH₃, CH(CH₃)₂, C(CH₃)₃, CF₃, CHF₂, C₃F₈ or phenyl.

3. The organometallic compound as claimed in claim 1, wherein the organometallic compound has a structure represented by Formula (III) or Formula (IV): 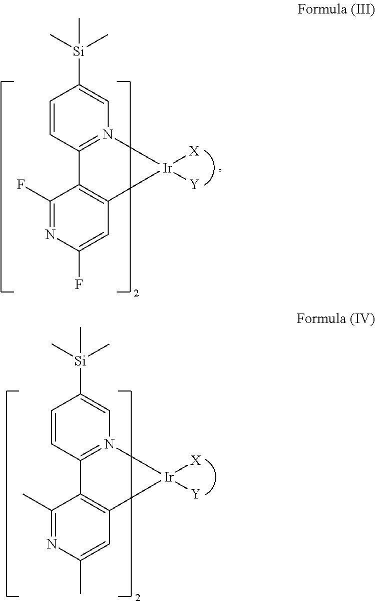
wherein 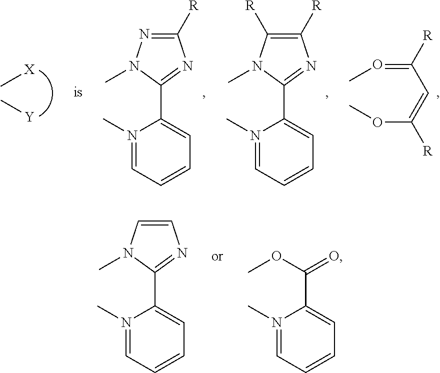
R is CH₃, CH₂CH₃, CH(CH₃)₂, C(CH₃)₃, CF₃, CHF₂, C₃F₈ or phenyl.

4. The organometallic compound as claimed in claim 1, wherein the organometallic compound is

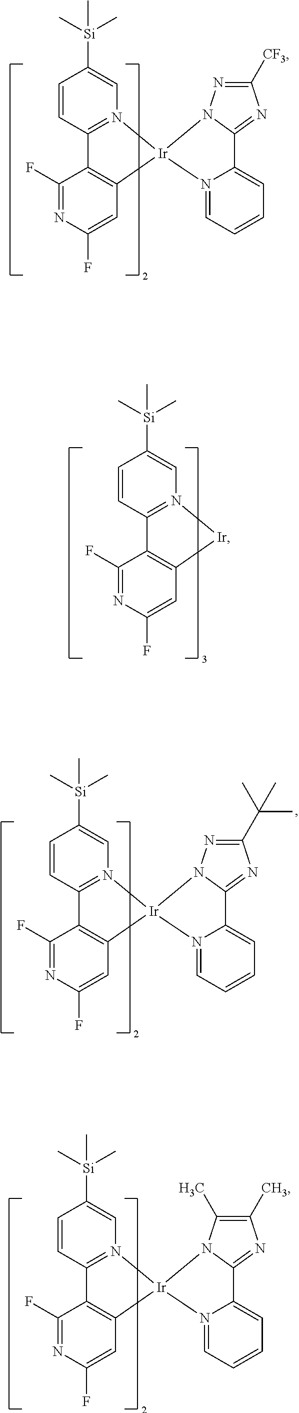

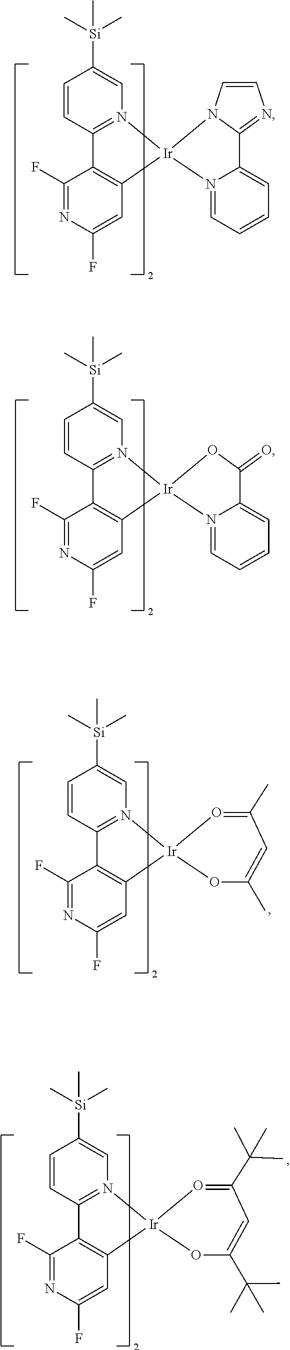

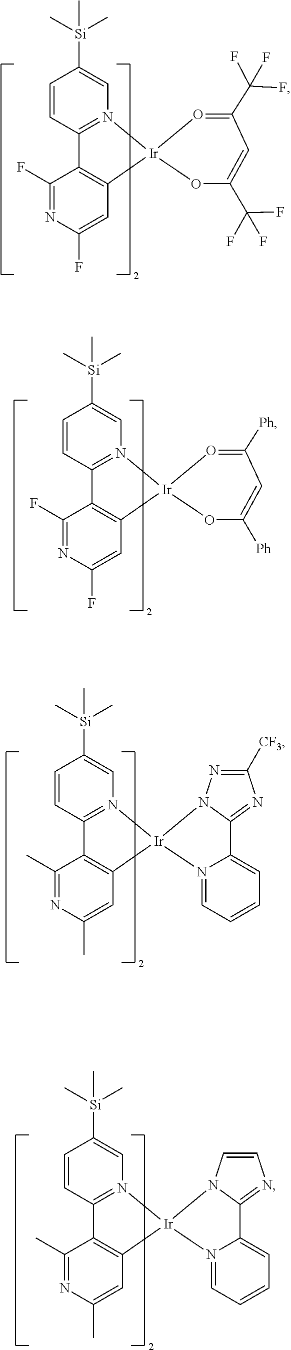

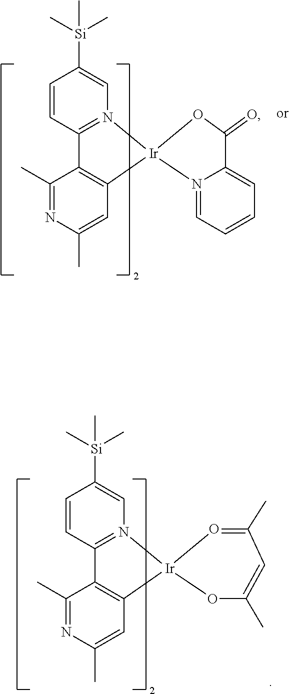

5. An organic light-emitting device, comprising:
an anode and a cathode; and
an organic light-emitting element disposed between the anode and the cathode,
wherein the organic light-emitting element comprises a organometallic 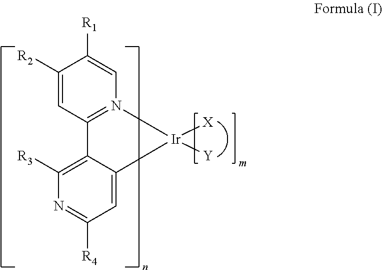
wherein, one of R₁ and R₂ is trimethylsilyl (TMS) and the other is hydrogen, at least one of R₃ and R₄ is fluorine or C₁₋₆ alkyl, or one of R₃ and R₄ is fluorine and the other is C₁₋₆ alkyl, 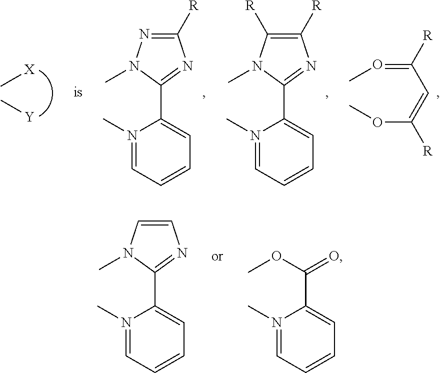
is CH₃, CH₂CH₃, CH(CH₃)₂, C(CH₃)₃, CF₃, CHF₂, C₃F₈ or phenyl, n is 2 or 3, and m is 0 or 1, wherein n+m=3.

6. The organic light-emitting device as claimed in claim 5, wherein the organometallic compound has a structure as defined by Formula (II): 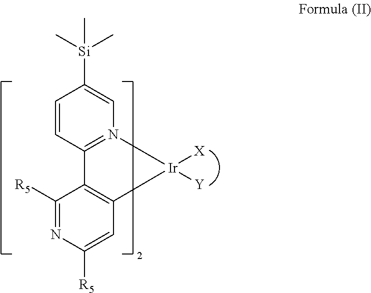
wherein R₅ is fluorine or C₁₋₆ alkyl, 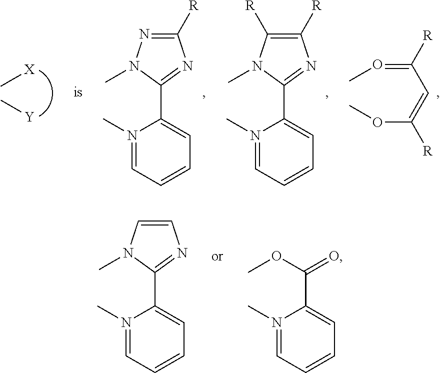
R is CH₃, CH₂CH₃, CH(CH₃)₂, C(CH₃)₃, CF₃, CHF₂, C₃F₈ or phenyl.

7. The organic light-emitting device as claimed in claim 5, wherein the organometallic compound has a structure represented by Formula (III) or Formula (IV): 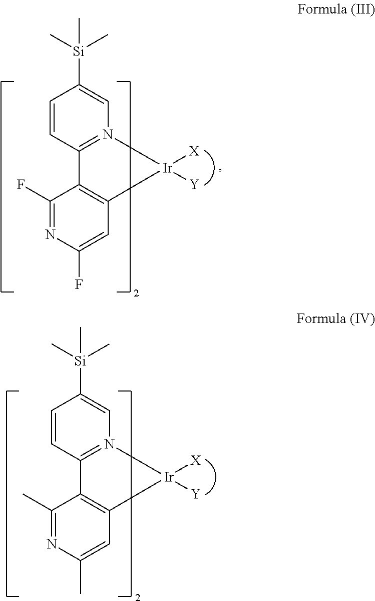
wherein 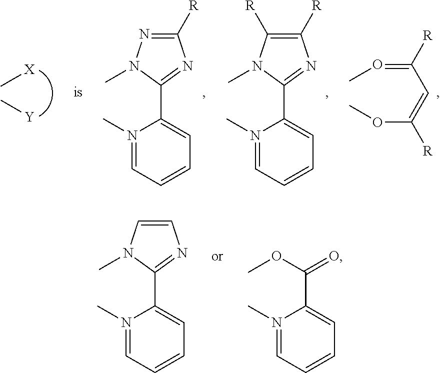
R is CH₃, CH₂CH₃, CH(CH₃)₂, C(CH₃)₃, CF₃, CHF₂, C₃F₈ or phenyl.

8. The organic light-emitting device as claimed in claim 5, wherein the organometallic compound is

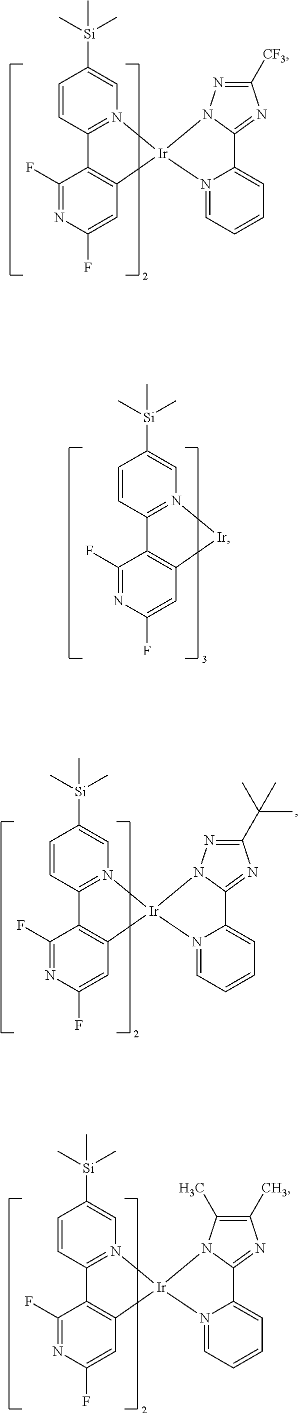

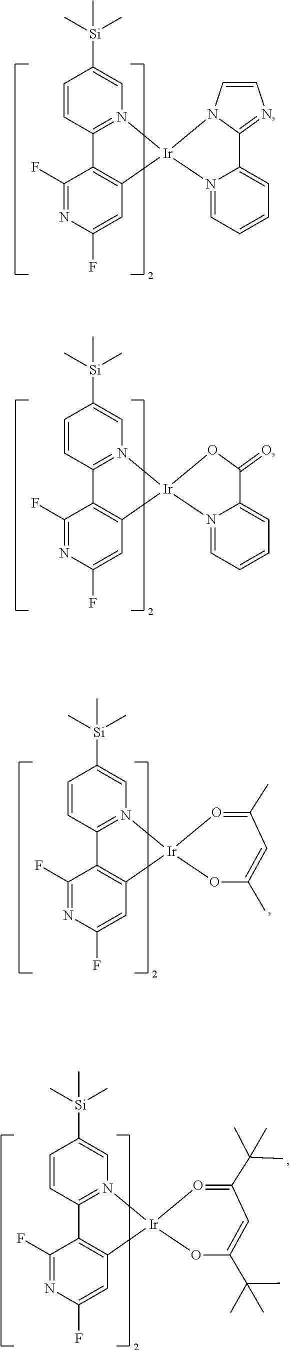

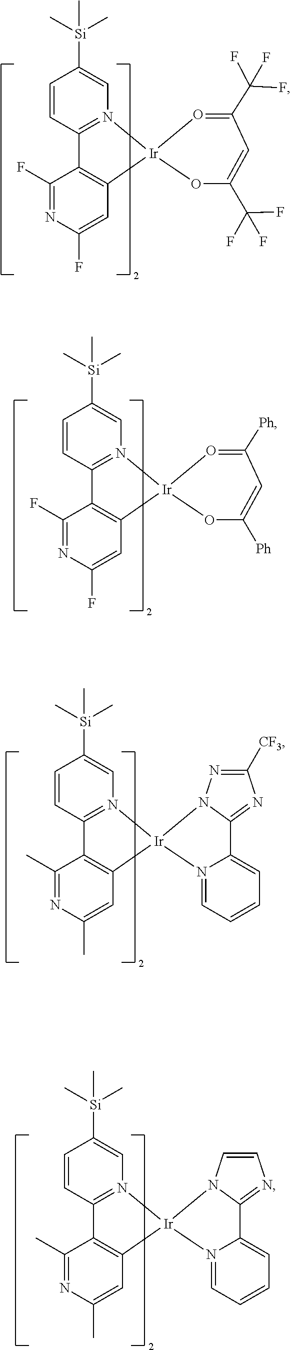

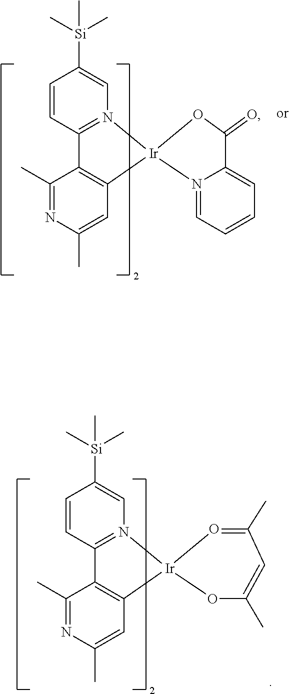

9. An organic light-emitting device, comprising:
an anode and a cathode; and
an organic light-emitting element disposed between the anode and the cathode,
wherein the organic light-emitting element comprises a first light-emitting layer, and the first light-emitting layer comprises a organometallic compound having a structure represented by the following Formula (I): 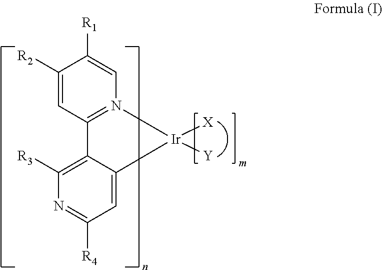
wherein, one of R₁ and R₂ is trimethylsilyl (TMS) and the other is hydrogen, at least one of R₃ and R₄ is fluorine or C₁₋₆ alkyl, or one of R₃ and R₄ is fluorine and the other is C₁₋₆ alkyl, 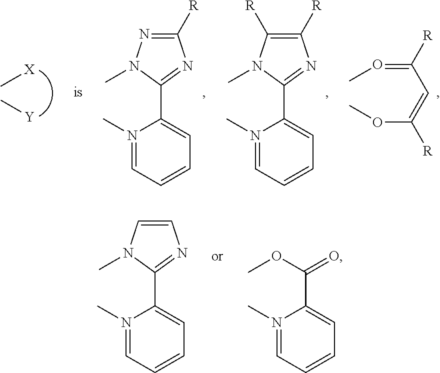
R is CH₃, CH₂CH₃, CH(CH₃)₂, C(CH₃)₃, CF₃, CHF₂, C₃F₈ or phenyl, n is 2 or 3, and m is 0 or 1, wherein n+m=3.

10. The organic light-emitting device as claimed in claim 9, wherein the first organometallic compound has a structure as defined by Formula (II): 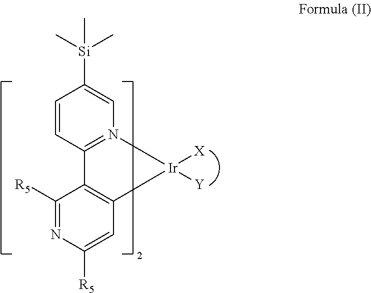
wherein R₅ is fluorine or C₁₋₆ alkyl, 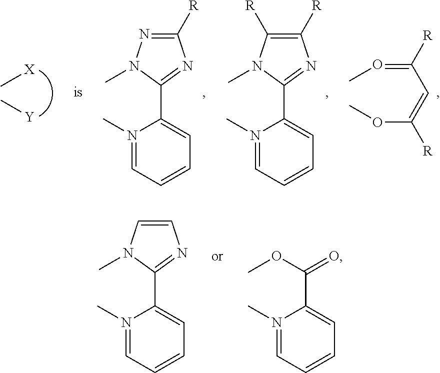
R is CH₃, CH₂CH₃, CH(CH₃)₂, C(CH₃)₃, CF₃, CHF₂, C₃F₈ or phenyl.

11. The organic light-emitting device as claimed in claim 9, wherein the first organometallic compound has a structure represented by Formula (III) or Formula (IV): 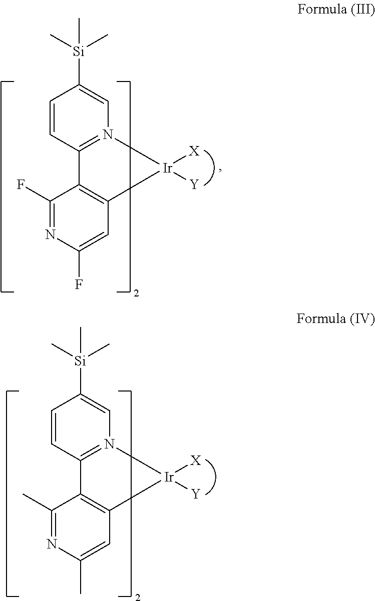
wherein 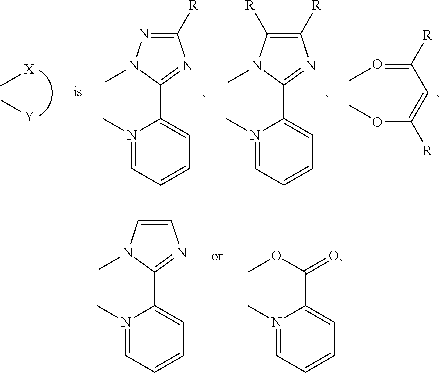
R is CH₃, CH₂CH₃, CH(CH₃)₂, C(CH₃)₃, CF₃, CHF₂, C₃F₈ or phenyl.

12. The organic light-emitting device as claimed in claim 9, wherein the first organometallic compound is

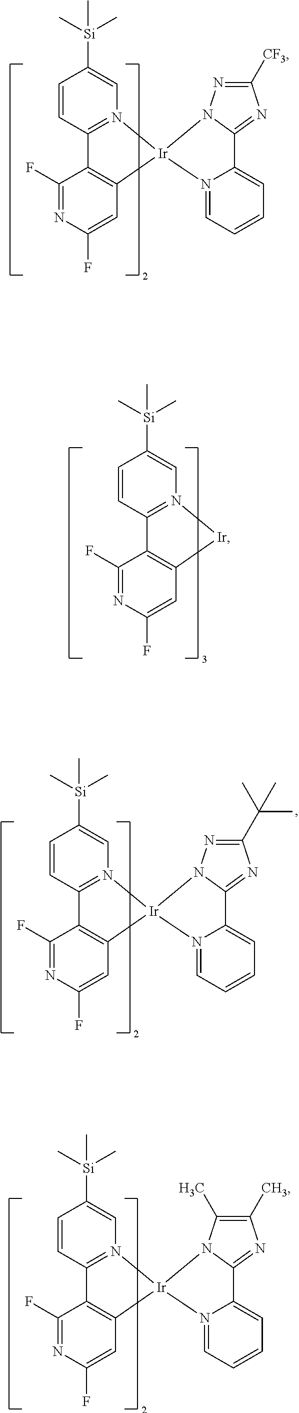

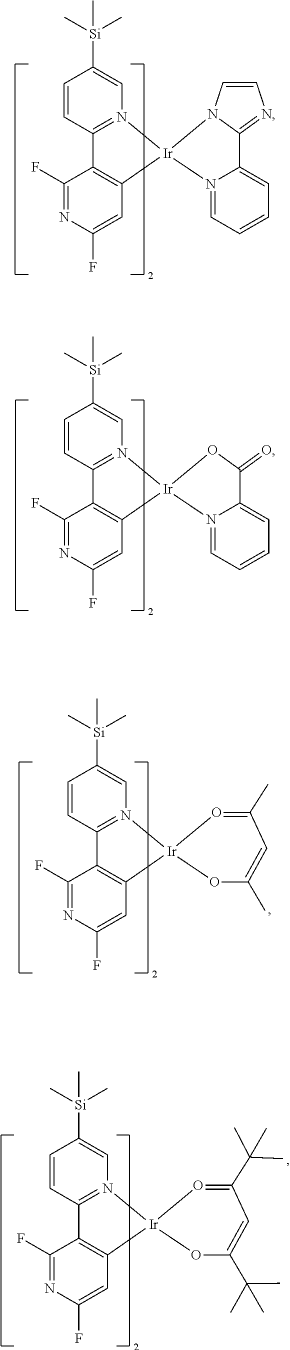

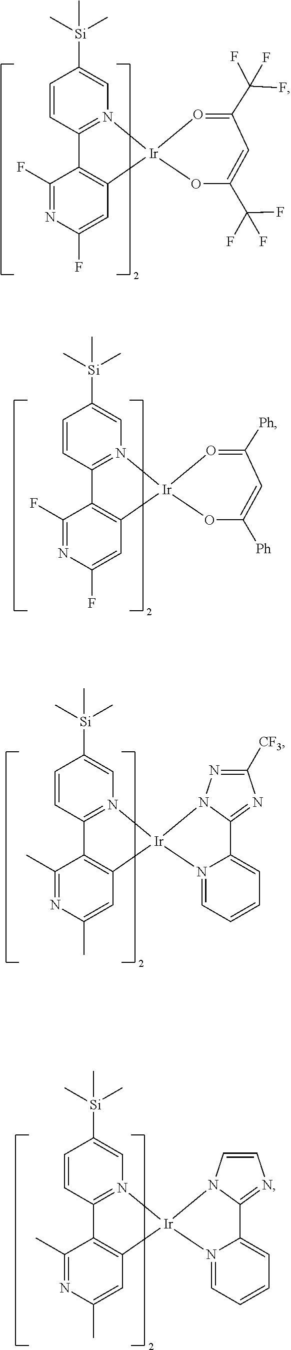

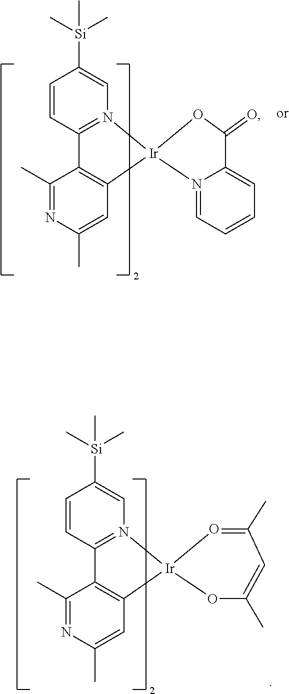

13. The organic light-emitting device as claimed in claim 9, further comprising a second light-emitting layer disposed between the anode and the first light-emitting layer or between the first light-emitting layer and the cathode.

14. The organic light-emitting device as claimed in claim 9, wherein the second light-emitting layer comprises a organometallic compound having a structure represented by the following Formula (I): 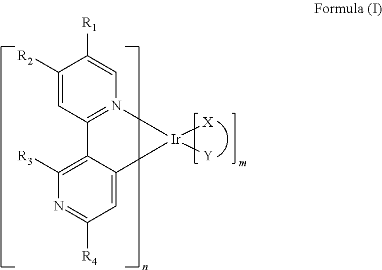
wherein, one of R₁ and R₂ is trimethylsilyl (TMS) and the other is hydrogen, at least one of R₃ and R₄ is fluorine or C₁₋₆ alkyl, or one of R₃ and R₄ is fluorine and the other is C₁₋₆ alkyl, 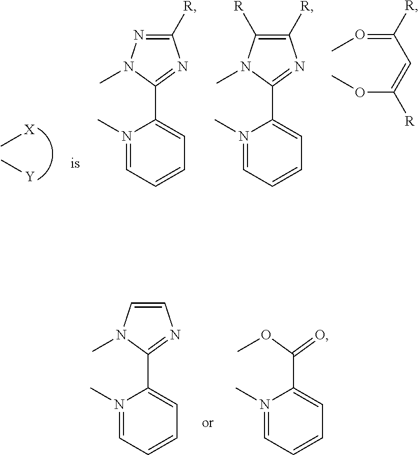
R is CH₃, CH₂CH₃, CH(CH₃)₂, C(CH₃)₃, CF₃, CHF₂, C₃F₈ or phenyl, n is 2 or 3, and m is 0 or 1, wherein n+m=3.

15. The organic light-emitting device as claimed in claim 9, wherein the organic light-emitting element emits blue light.
